(19) United States
(12) Patent Application Publication
(10) Pub. No.: US 2024/0292654 A1
(43) Pub. Date: Aug. 29, 2024

(54) Display Substrate and Display Apparatus

(71) Applicants: Chengdu BOE Optoelectronics Technology Co., Ltd., Chengdu , Sichuan (CN); BOE Technology Group Co., Ltd., Beijing (CN)

(72) Inventors: Yao HUANG, Beijing (CN); Shiqi LI, Beijing (CN); Jing ZHANG, Beijing (CN)

(21) Appl. No.: 18/023,001

(22) PCT Filed: Feb. 24, 2022
(86) PCT No.: PCT/CN2022/077687

§ 371 Date: Feb. 24, 2023

(51) Int. Cl. H10K 59/10

(52) U.S. Cl. CPC H10K 59/10

(57) ABSTRACT

Provided are a display substrate and a display apparatus. A display substrate includes a display area and a bonding area, the display area includes a first display area and a second display area; the first display area includes a first sub-pixel and a first data line, and the second display area includes a second sub-pixel and a second data line; the bonding area includes a detection circuit, the detection circuit includes a control line, a first signal line, a second signal line, a first detection sub-unit and a second detection sub-unit; the first detection sub-unit is configured to output a signal transmitted by the first signal line to the first data line, and the second detection sub-unit is configured to output a signal transmitted by the second signal line to the second data line.

### CROSS-REFERENCE TO RELATED APPLICATION

The present application is a U.S. National Phase Entry of International Application PCT/CN2022/077687 having an international filing date of Feb. 24, 2022, and the contents disclosed in the above-mentioned application are hereby incorporated as a part of this application.

### TECHNICAL FIELD

The present disclosure relates to, but is not limited to, the field of display technology, in particular to a display substrate and a display apparatus.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption and very high response speed. With continuous development of display technologies, a display apparatus using the OLED or the QLED as a light emitting device and using a Thin Film Transistor (TFT) for signal control has become a mainstream product in the field of display at present.

### SUMMARY

The following is a summary of subject matter described herein in detail. The summary is not intended to limit the protection scope of claims.

In one aspect, an exemplary embodiment of the present disclosure provide a display substrate, comprising a display area and a bonding area located on a side of the display area, wherein the display area includes a first display area and a second display area, the first display area at least partially surrounding the second display area, the first display area is configured to display an image, and the second display area is configured to display an image and allow light to transmit; the first display area includes multiple first sub-pixels and at least one first data line connected to the first sub-pixels, and the second display area including multiple second sub-pixels and at least one second data line connected to the second sub-pixels; the bonding area includes a detection circuit, wherein the detection circuit includes control lines, first signal lines, second signal lines, at least one first detection sub-unit and at least one second detection sub-unit; a control end of a first detection sub-unit is connected to a control line, an input end of the first detection sub-unit is connected to a first signal line, an output end of the first detection sub-unit is connected to a first data line, the first detection sub-unit is configured to output a signal transmitted by the first signal line to the first data line; a control end of a second detection sub-unit is connected to a control line, an input end of the second detection sub-unit is connected to a second signal line, an output end of the second detection sub-unit is connected to a second data line, and the second detection sub-unit is configured to output a signal transmitted by the second signal line to the second data line.

In an exemplary implementation, the control lines include a first control line, a second control line and a third control line, wherein the first signal lines include a first detection line, a third detection line and a fifth detection line, the second signal lines include a second detection line, a fourth detection line, and a sixth detection line, the first detection sub-unit includes an eleventh switch unit, a twelfth switch unit and a thirteenth switch unit, and the second detection sub-unit includes a twenty-first switch unit, a twenty-second switch unit and a twenty-third switch unit; the eleventh switch unit is configured to transmit a signal transmitted by the first detection line to a first data line connected to a first color sub-pixel in the first display area under control of the first control line; the twelfth switch unit is configured to transmit a signal transmitted by the third detection line to a first data line connected to a second color sub-pixel in the first display area under the control of second control line; the thirteenth switch unit is configured to transmit a signal transmitted by the fifth detection line to a first data line connected to a third color sub-pixel in the first display area under control of the third control line; the twenty-first switch unit is configured to transmit a signal transmitted by the second detection line to a second data line connected to a first color sub-pixel in the second display area under the control of the first control line; the twenty-second switch unit is configured to transmit a signal transmitted by the fourth detection line to a second data line connected to a second color sub-pixel in the second display area under the control of the second control line; and the twenty-third switch unit is configured to transmit a signal transmitted by the sixth detection line to a second data line connected to a third color sub-pixel in the second display area under the control of the third control line.

In an exemplary implementation, a control end of the eleventh switch unit is connected to the first control line, an input end of the eleventh switch unit is connected to the first detection line, and an output end of the eleventh switch unit is connected to the first data line connected to the first color sub-pixel in the first display area; a control end of the twenty-first switch unit is connected to the first control line, an input end of the twenty-first switch unit is connected to the second detection line, and an output end of the twenty-first switch unit is connected to the second data line connected to the first color sub-pixel in the second display area.

In an exemplary implementation, the eleventh switch unit includes at least one eleventh transistor, wherein a control electrode of an eleventh transistor is connected to the first control line, a first electrode of the eleventh transistor is connected to the first detection line, and a second electrode of the eleventh transistor is connected to the first data line connected to the first color sub-pixel in the first display area; and the twenty-first switch unit includes at least one twenty-first transistor, wherein a control electrode of a twenty-first transistor is connected to the first control line, a first electrode of the twenty-first transistor is connected to the second detection line, and a second electrode of the twenty-first transistor is connected to the second data line connected to the first color sub-pixel in the second display area.

In an exemplary implementation, a control end of the twelfth switch unit is connected to the second control line, an input end of the twelfth switch unit is connected to the third detection line, and an output end of the twelfth switch unit is connected to the first data line connected to the second color sub-pixel in the first display area; and a control end of the twenty-second switch unit is connected to the second control line, an input end of the twenty-second switch unit is connected to the fourth detection line, and an output end of the twenty-second switch unit is connected to the second data line connected to the second color sub-pixel in the second display area.

In an exemplary implementation, the twelfth switch unit includes at least one twelfth transistor and at least one thirteenth transistor, wherein control electrodes of the at least one twelfth transistor and the at least one thirteenth transistor are connected to the second control line, first electrodes of the at least one twelfth transistor and the at least one thirteenth transistor are connected to the third detection line, and second electrodes of the at least one twelfth transistor and the at least one thirteenth transistor are connected to the first data line connected to the second color sub-pixel in the first display area; and the twenty-second switch unit includes at least one twenty-second transistor and at least one twenty-third transistor, wherein control electrodes of the at least one twenty-second transistor and the at least one twenty-third transistor are connected to the second control line, first electrodes of the at least one twenty-second transistor and the twenty-third transistor are connected to the fourth detection line, and second electrodes of the at least one twenty-second transistor and the at least one twenty-third transistor are connected to the second data line connected to the second color sub-pixel in the second display area.

In an exemplary implementation, a control end of the thirteenth switch unit is connected to the third control line, an input end of the thirteenth switch unit is connected to the fifth detection line, and an output end of the thirteenth switch unit is connected to the first data line connected to the third color sub-pixel in the first display area; and a control end of the twenty-third switch unit is connected to the third control line, an input end of the twenty-third switch unit is connected to the sixth detection line, and an output end of the twenty-third switch unit is connected to the second data line connected to the third color sub-pixel in the second display area.

In an exemplary implementation, the thirteenth switch unit includes at least one fourteenth transistor and at least one fifteenth transistor, wherein control electrodes of the at least one fourteenth transistor and the at least one fifteenth transistor are connected to the third control line, first electrodes of the at least one fourteenth transistor and the at least one fifteenth transistor are connected to the fifth detection line, and second electrodes of the at least one fourteenth transistor and the at least one fifteenth transistor are connected to the first data line connected to the third color sub-pixel in the first display area; and the twenty-third switch unit includes at least one twenty-fourth transistor and at least one twenty-fifth transistor, wherein control electrodes of the at least one twenty-fourth transistor and the at least one twenty-fifth transistor are connected to the third control line, first electrodes of the at least one twenty-fourth transistor and the at least one twenty-fifth transistor are connected to the sixth detection line, and second electrodes of the at least one twenty-fourth transistor and the at least one twenty-fifth transistor are connected to the second data line connected to the third color sub-pixel in the second display area.

In an exemplary implementation, the detection circuit further comprises a switching control line and a switching unit, wherein a control electrode of the switching unit is connected with the switching control line, a first electrode of the switching unit is connected to the first signal lines, a second electrode of the switching unit is connected to the second signal lines, and the switching unit is configured to isolate or turn on the first signal lines and the second signal lines under control of the switching control line.

In an exemplary implementation, the switching unit includes a first switching sub-unit, a second switching sub-unit and a third switching sub-unit; the first signal lines include a first detection line, a third detection line and a fifth detection line; the second signal lines include a second detection line, a fourth detection line and a sixth detection line; a control electrode of the first switching sub-unit is connected to the switching control line, a first electrode of the first switching sub-unit is connected to the first detection line, and a second electrode of the first switching sub-unit is connected to the second detection line; a control electrode of the second switching sub-unit is connected to the switching control line, a first electrode of the second switching sub-unit is connected to the third detection line, and a second electrode of the second switching sub-unit is connected to the fourth detection line; and a control electrode of the third switching sub-unit is connected to the switching control line, a first electrode of the third switching sub-unit is connected to the fifth detection line, and a second electrode of the third switching sub-unit is connected to the sixth detection line.

In an exemplary implementation, the first switching sub-unit includes two first transistors connected in series, wherein control electrodes of the two first transistors are connected to the switching control line, a first electrode of one first transistor is connected to the first detection line, a second electrode of the other first transistor is connected to the second detection line, and a second electrode of the one first transistor and a first electrode of the other first transistor are connected to each other.

In an exemplary implementation, the second switching sub-unit includes two second transistors connected in series, wherein control electrodes of the two second transistors are connected to the switching control line, a first electrode of one second transistor is connected to the third detection line, a second electrode of the other second transistor is connected to the fourth detection line, and a second electrode of the one second transistor and a first electrode of the other second transistor are connected to each other.

In an exemplary implementation, the third switching sub-unit includes two third transistors connected in series, wherein control electrodes of the two third transistors are connected to the switching control line, a first electrode of one third transistor is connected to the fifth detection line, a second electrode of the other third transistor is connected to the sixth detection line, and a second electrode of the one third transistor and a first electrode of the other third transistor are connected to each other.

In an exemplary implementation, the detection circuit further includes a switch control line, a switch unit and a signal lead, wherein a control electrode of the switch unit is connected to the switch control line, a first electrode of the switch unit is connected to the signal lead, a second electrode of the switch unit is connected to the second signal line, and the switch unit is configured to isolate or turn on the signal lead and the second signal line under the control of the switch control line; when the signal lead and the second signal line are turned on, the first signal line and the second signal line are isolated from each other, and the first signal line and the second signal line output different aging voltage signals; and when the signal lead and the second signal line are isolated from each other, the first signal line and the second signal line are turned on, and the first signal line and the second signal line output a same Light-on voltage signal.

In an exemplary implementation, on a plane perpendicular to the display substrate, the display substrate includes a semiconductor layer, a first conductive layer, a second conductive layer and a third conductive layer arranged sequentially on a base substrate, wherein the semiconductor layer includes active layers of multiple transistors in the switching unit, active layers of multiple transistors in the at least one first detection sub-unit and active layers of multiple transistors in the at least one second detection sub-unit, the first conductive layer includes gate electrodes of the multiple transistors in the switching unit, gate electrodes of the multiple transistors in the at least one first detection sub-unit, and gate electrodes of the multiple transistors in the at least one second detection sub-unit, and the third conductive layer includes the control lines, the first signal lines, and the second signal lines.

In an exemplary implementation, the control lines include a first control line, a second control line and a third control line, wherein at least one of the first control line, the second control line and the third control line includes a control lead-out line and a control extension line, the control lead-out line and the control extension line are connected through a signal connection line arranged in the first conductive layer, and the control lead-out line and the control extension line are arranged in the third conductive layer.

In an exemplary implementation, the first signal lines include a first detection line, a third detection line and a fifth detection line, the second signal lines include a second detection line, a fourth detection line and a sixth detection line, and at least one of the first detection line, the second detection line, the third detection line, the fourth detection line, the fifth detection line and the sixth detection line includes a detection lead-out line and a detection extension line, the detection lead-out line and the detection extension line are connected through a signal connection line arranged in the first conductive layer, and the detection lead-out line and the detection extension line are arranged in the third conductive layer.

In an exemplary implementation, the first conductive layer further includes a switching connection line, the third conductive layer further includes a switching control line connected to the switching control line through a via, and the switching connection line and gate electrodes of multiple transistors in the switching unit are connected to each other to form an integral structure.

In an exemplary implementation, a first detection sub-unit includes a first transmission line and a second transmission line, wherein the first transmission line is connected to a first data line connected to a first color sub-pixel in the first display area and the second transmission line is connected to a first data line connected to a second color sub-pixel and a third color sub-pixel in the first display area; and the first transmission line is arranged in the first conductive layer, and the second transmission line is arranged in the second conductive layer.

In an exemplary implementation, a twenty-first connection block and a twenty-second connection block are provided on the second transmission line; the twenty-first connection block is connected to a twelfth active layer and a thirteenth active layer in the first detection sub-unit through a twelfth connection electrode, and the twenty-first connection block is arranged between the twelfth active layer and the thirteenth active layer; and the twenty-second connection block is connected to a fourteenth active layer and a fifteenth active layer in the first detection sub-unit through a thirteenth connection electrode, and the twenty-second connection block is arranged between the fourteenth active layer and the fifteenth active layer.

In an exemplary implementation, the twelfth connection electrode and the thirteenth connection electrode are arranged in the third conductive layer.

In an exemplary implementation, a second detection sub-unit includes a third transmission line a fourth transmission line, the third transmission line is connected to a second data line connected to a first color sub-pixel in the second display area, and the fourth transmission line is connected to a second data line connected to a second color sub-pixel and a third color sub-pixel in the second display area, and the third transmission line is arranged in the first conductive layer, and the fourth transmission line is arranged in the second conductive layer.

In an exemplary implementation, a forty-first connection block, a forty-second connection block, a forty-third connection block and a forty-fourth connection block are provided on the fourth transmission line; the forty-first connection block is connected to a twenty-second active layer in the second detection sub-unit through a twenty-second connection electrode, and the forty-first connection block is arranged on a side of the twenty-second active layer in a first direction; the forty-second connection block is connected to a twenty-third active layer in the second detection sub-unit through a twenty-third connection electrode, and the forty-second connection block is arranged on a side of the twenty-third active layer in a direction opposite to the first direction; the forty-third connection block is connected to a twenty-fourth active layer in the second detection sub-unit through a twenty-fourth connection electrode, and the forty-third connection block is arranged on a side of the twenty-fourth active layer in the first direction; the forty-fourth connection block is connected to a twenty-fifth active layer in the second detection sub-unit through a twenty-fifth connection electrode, and the forty-fourth connection block is arranged on a side of the twenty-fifth active layer in the direction opposite to the first direction; and the first direction is an extension direction of the fourth transmission line.

In an exemplary implementation, the twenty-second connection electrode, the twenty-third connection electrode, the twenty-fourth connection electrode, and the twenty-fifth connection electrode are arranged in the third conductive layer.

According to another aspect, an exemplary embodiment of the present disclosure further provides a display apparatus, which includes any one of the aforementioned display substrate described in.

Other aspects may be comprehended upon reading and understanding drawings and detailed descriptions.

### BRIEF DESCRIPTION OF DRAWINGS

Accompanying drawings are used for providing further understanding of technical solutions of the present disclosure, constitute a part of the specification, and are used for explaining the technical solutions of the present disclosure together with the embodiments of the present disclosure but not to constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display apparatus.

FIG. 2 is a schematic diagram of a planar structure of a display substrate.

FIG. 3 is a schematic diagram of a planar structure of a first display area.

FIG. 4 is a schematic diagram of a sectional structure of a first display area.

FIG. 5 is an equivalent circuit diagram of a pixel drive circuit.

FIG. 6 is an operating timing diagram of a pixel drive circuit.

FIG. 7 is a schematic diagram of a planar structure of a bonding area in a display substrate.

FIG. 8 is an equivalent circuit diagram of a detection circuit.

FIG. 9a and FIG. 9b are equivalent circuit diagrams of a detection circuit according to an exemplary embodiment of the present disclosure.

FIG. 10 is a equivalent circuit diagram of another detection circuit according to an exemplary embodiment of the present disclosure.

FIG. 11 is an equivalent circuit diagram of another detection circuit according to an exemplary embodiment of the present disclosure.

FIG. 12a to FIG. 12c are schematic diagrams after a pattern of a semiconductor layer is formed according to an exemplary embodiment of the present disclosure.

FIG. 13a to FIG. 13c are schematic diagrams after a pattern of a first conductive layer is formed according to an exemplary embodiment of the present disclosure.

FIG. 14a and FIG. 14b are schematic diagrams after a pattern of a second conductive layer is formed according to an exemplary embodiment of the present disclosure.

FIG. 15a to FIG. 15c are schematic diagrams after a pattern of a fourth insulation layer is formed according to an exemplary embodiment of the present disclosure.

FIG. 16a to FIG. 16c are schematic diagrams after a pattern of a third conductive layer is formed according to an exemplary embodiment of the present disclosure.

FIG. 17 is a schematic diagram of a structure of a detection circuit connected to a pin according to an exemplary embodiment of the present disclosure.

FIG. 18 is an equivalent circuit diagram of another detection circuit according to an exemplary embodiment of the present disclosure.

### DETAILED DESCRIPTION

The embodiments of the present disclosure will be described in detail below with reference to the drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict.

Scales of the drawings in the present disclosure may be used as a reference in actual processes, but are not limited thereto. For example, a width-length ratio of a channel, thickness and spacing of each film layer, and width and spacing of each signal line may be adjusted according to actual needs. The number of pixels in a display substrate and the number of sub-pixels in each pixel are not limited to the numbers shown in the drawings. The drawings described in the present disclosure are schematic structural diagrams only, and one implementation of the present disclosure is not limited to the shapes, numerical values or the like shown in the drawings.

Ordinal numerals such as “first”, “second”, and “third” in the specification are set to avoid confusion between constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, it may be a fixed connection, a detachable connection, or an integrated connection, it may be a mechanical connection or a connection, it may be a direct connection, an indirect connection through an intermediate component, or internal communication between two components. Those of ordinary skills in the art may understand specific meanings of these terms in the present disclosure according to specific situations.

In the specification, a transistor refers to an element which includes at least three terminals, i.e., a gate electrode, a drain electrode and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, the first electrode may be the source electrode, and the second electrode may be the drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode” are interchangeable in the specification.

In this specification, a “connection” includes a case where constitute elements are connected to each other through an element having certain electrical effect. The “element with the certain electrical effect” is not particularly limited as long as electrical signals may be sent and received between the connected constituent elements. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon and hexagon in this specification are not strictly defined, and they may be approximate triangle, rectangle, trapezoid, pentagon or hexagon, etc. There may be some small deformation caused by tolerance, and there may be guide angle, arc edge and deformation, etc.

In the present disclosure, “about” refers to that a boundary is defined not so strictly and numerical values within process and measurement error ranges are allowed.

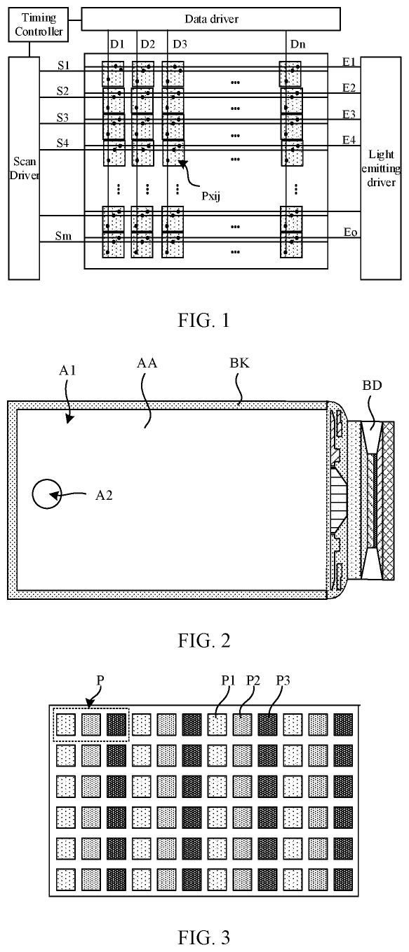

FIG. 1 is a schematic diagram of a structure of a display apparatus. As shown in FIG. 1, the display apparatus may include a timing controller, a data driver, a scan driver, a light emitting driver and a pixel array. The timing controller is connected to the data driver, the scan driver and the light emitting driver, respectively. The data driver is connected to multiple data lines (D1 to Dn) respectively. The scan driver is connected to multiple scan signal lines (S1 to Sm) respectively. The light emitting driver is connected to multiple light emitting signal lines (E1 to Eo) respectively. The pixel array may include multiple sub-pixels Pxij, i and j may be natural numbers. At least one sub-pixel Pxij may include a circuit unit and a light emitting device connected to the circuit unit, and the circuit unit may include at least one scan signal line, at least one data line, at least one light emitting signal line and a pixel drive circuit. In an exemplary implementation, the timing controller may provide the data driver with a grayscale value and a control signal which are suitable for a specification of the data driver, provide the scan driver with a clock signal, a scan start signal and the like which are suitable for a specification of the scan driver, and provide the light emitting driver with a clock signal, an emission stop signal and the like which are suitable for a specification of the light emitting driver. The data driver may generate a data voltage to be provided to the data lines D1, D2, D3, . . . , and Dn by using the grayscale value and the control signal that are received from the timing controller. For example, the data driver may sample the grayscale value by using the clock signal and apply a data voltage corresponding to the grayscale value to the data lines D1 to Dn by taking a pixel row as a unit, wherein n may be a natural number. The scan driver may receive the clock signal, the scan start signal and the like from the timing controller to generate a scan signal to be provided to the scan signal lines S1, S2, S3, . . . , and Sm. For example, the scan driver may provide a scan signal with an on-level pulse to the scan signal lines S1 to Sm sequentially. For example, the scan driver may be constructed in a form of a shift register and may generate a scan signal by sequentially transmitting the scan start signal provided in a form of an on-level pulse to a next-stage circuit under the control of the clock signal, wherein m may be a natural number. The light emitting driver may receive the clock signal, the emission stop signal and the like from the timing controller to generate an emission signal to be provided to the light emitting signal lines E1, E2, E3, . . . , and Eo. For example, the light emitting driver may provide an emission signal with an off-level pulse to the light emitting signal lines E1 to Eo sequentially. For example, the light emitting driver may be constructed in a form of a shift register and may generate an emission signal by sequentially transmitting the emission stop signal provided in a form of an off-level pulse to a next-stage circuit under the control of the clock signal, wherein o may be a natural number.

With the development of display technology, products such as full screen or narrow bezel displays have gradually become a development trend of display products due to their large screen-to-body ratio and ultra-narrow bezel. For a product such as an intelligent terminal, a front camera, a fingerprint sensor, or a light sensor usually needs to be arranged. In order to increase screen-to-body ratio, under-screen fingerprint or Full display with camera technology (FDC for short) is usually adopted for a product with full screen or narrow bezel, and sensors such as cameras are placed in a Under Display Camera (UDC for short) area of the display substrate. The UDC area not only has certain transmittance, but also has display function.

FIG. 2 is a schematic diagram of a planar structure of a display substrate. As shown in FIG. 2, in a plane parallel to the display substrate, the display substrate may include a display area AA, a bonding area BD on a side of the display area AA, and a bezel area BK on other sides of the display area AA. The display area AA may include multiple sub-pixels configured to display a dynamic picture or a static image. The bonding area BD may include data fan-out lines connecting multiple data lines to an integrated circuit. The bezel area BK may include a power supply line for transmitting a voltage signal. The bonding area BD and the bezel area BK may include an isolation dam of an annular structure, which is not limited in the present disclosure.

In an exemplary implementation, the display area AA may include a first display area A1 and a second display area A2, wherein the first display area A1 may at least partially surround the second display area A2. In an exemplary implementation, the first display area A1 is configured to display an image. A position of the second display area A2 may correspond to a position of an optical apparatus, and the second display area A2 is configured to display an image and transmit light, with the transmitted light being received by the optical apparatus. In an exemplary implementation, the first display area may be referred to as a normal display area and the second display area may be referred to as a photographing display area.

In an exemplary implementation, a position of the second display area A2 within the first display area A1 is not limited, and may be located at an upper or lower portion of the first display area A1, or may be located at an edge of the first display area A1. In a plane parallel to the display apparatus, a shape of the second display area A2 may be any one or more of the following: rectangle, polygon, circle and ellipse, and the optical apparatus may be an optical sensor such as a fingerprint identification apparatus, a photographing apparatus, or a 3D imaging apparatus.

In an exemplary implementation, resolutions of the first display area A1 and the second display area A2 may be the same, or the resolution of the second display area A2 may be less than that of the first display area A1. For example, the resolution of the second display area A2 may be about 50% to 70% of the resolution of the first display area A1. Pixels Per Inch (PPI) refers to the number of pixels per unit area, which can be called a pixel density. The higher the PPI value, the higher a density with which the display substrate can display a picture, and the richer the details of the picture.

FIG. 3 is a schematic diagram of a planar structure of a first display area. As shown in FIG. 3, the first display area may include multiple pixel units P arranged in a matrix. At least one of the multiple pixel units P may include a first sub-pixel P1 emitting light of a first color, a second sub-pixel P2 emitting light of a second color, and a third sub-pixel P3 emitting light of a third color. The three sub-pixels each include a pixel drive circuit and a light emitting device, wherein the pixel drive circuit in each of the three sub-pixels is respectively connected to a scan signal line, a signal line and a light emitting signal line, and the pixel drive circuit is configured to receive a data voltage transmitted by the data line and output a corresponding current to the light emitting device, under the control of the scan signal line and the light emitting signal line. The light emitting device in each of the three sub-pixels is connected to a pixel drive circuit of a sub-pixel where the light emitting device is located, and is configured to emit light with a corresponding brightness in response to a current output by the pixel drive circuit of the sub-pixel where the light emitting device is located.

In an exemplary implementation, the first sub-pixel P1 may be a red sub-pixel emitting red (R) light, the second sub-pixel P2 may be a blue sub-pixel emitting blue (B) light, the third sub-pixel P3 may be a green sub-pixel emitting green (G) light. A shape of the sub-pixels may be rectangular, diamond-shaped, pentagonal, hexagonal, or the like, and the sub-pixels may be arranged side by side horizontally, side by side vertically, or in a triangle-shaped arrangement.

In an exemplary implementation, a pixel unit may include four sub-pixels which may be arranged side by side horizontally, side by side vertically, in a square, in a diamond shape, or the like, which is not limited here in the present disclosure.

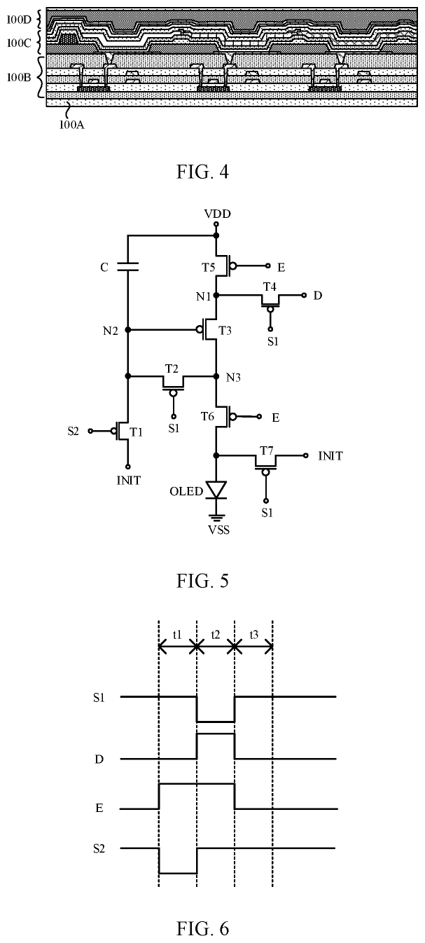

FIG. 4 is a schematic diagram of a sectional structure of a first display area, and illustrates a structure of three sub-pixels of the first display area. As shown in FIG. 4, on a plane perpendicular to the display substrate, the first display area may include a drive circuit layer 100B arranged on a base substrate 100A, a light emitting structure layer 100C arranged at a side of the drive circuit layer 100B away from the base substrate, and an encapsulation structure layer 100D arranged at a side of the light emitting structure layer 100C away from the base substrate. In some possible implementations, the display substrate may include another film layer, such as a post spacer, which is not limited in the present disclosure.

In an exemplary implementation, the base substrate 100A may be a flexible base substrate, or a rigid base substrate. The flexible base substrate may include a first flexible material layer, a first inorganic material layer, a semiconductor layer, a second flexible material layer and a second inorganic material layer which are stacked. Materials of the first flexible material layer and the second flexible material layer may be polyimide (P1), polyethylene terephthalate (PET) or a polymer soft film with surface treatment. Materials of the first inorganic material layer and the second inorganic material layer may be silicon nitride (SiNx) or silicon oxide (SiOx), for improving water and oxygen resistance of the base substrate, and a material of the semiconductor layer may be amorphous silicon (a-si).

In an exemplary implementation, the drive circuit layer 100B of each sub-pixel may include a pixel drive circuit formed by multiple transistors and a storage capacitor, and in FIG. 4, for example, the pixel drive circuit includes one transistor and one storage capacitor. In some possible implementations, the drive circuit layer 100B of each sub-pixel may include: a first insulation layer arranged on the base substrate, an active layer arranged on the first insulation layer, a second insulation layer covering the active layer; a gate electrode and a first capacitor electrode arranged on the second insulation layer, a third insulation layer covering the gate electrode and the first capacitor electrode, a second capacitor electrode arranged on the third insulation layer, a fourth insulation layer covering the second capacitor electrode, vias formed on the second insulation layer, the third insulation layer, and the fourth insulation layer which expose the active layer, a source electrode and a drain electrode arranged on the fourth insulation layer, which are respectively connected to the active layer through vias, and a planarization layer covering the aforementioned structures, wherein the planarization layer is provided with a via, and the via exposes the drain electrode. The active layer, the gate electrode, the source electrode and the drain electrode constitute a drive transistor, and the first capacitor electrode and the second capacitor electrode constitute the storage capacitor.

In an exemplary implementation, the light emitting structure layer 100C of each sub-pixel may include a light emitting device composed of multiple film layers which may include at least an anode, a pixel definition layer, an organic light emitting layer and a cathode. The anode may be arranged on the planarization layer, and is connected to the drain electrode of the drive transistor through the via provided in the planarization layer. The pixel definition layer is arranged on the anode and the planarization layer, and is provided with a pixel opening to expose the anode. The organic light emitting layer is at least partially arranged in the pixel opening, and is connected to the anode. The cathode is arranged on the organic light emitting layer and is connected to the organic light emitting layer, and the organic light emitting layer is driven by the anode and the cathode to emit light with a corresponding color.

In an exemplary implementation, the encapsulation structure layer 100D may include a first encapsulation layer, a second encapsulation layer, and a third encapsulation layer that are stacked. The first encapsulation layer and the third encapsulation layer may be made of an inorganic material, and the second encapsulation layer may be made of an organic material and is arranged between the first encapsulation layer and the third encapsulation layer, which may ensure that outside moisture cannot enter the light light-emitting structure layer 100C.

In an exemplary implementation, the organic light emitting layer may include an emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In an exemplary implementation, hole injection layers, hole transport layers, electron block layers, hole block layers, electron transport layers, and electron injection layers of all sub-pixels may be a common layer communicated together. Emitting layers of adjacent sub-pixels may be overlapped slightly, or may be isolated with each other.

FIG. 5 is a schematic diagram of an equivalent circuit of a pixel drive circuit. In an exemplary implementation, the pixel drive circuit may have a structure of 3TIC, 4TIC, 5TIC, 5T2C, 6TIC, 7TIC or 8TIC. As shown in FIG. 5, the pixel drive circuit may include seven transistors (a first transistor T1 to a seventh transistor T7), and one storage capacitor C. The pixel drive circuit is respectively connected to seven signal lines (a data line D, a first scan signal line S1, a second scan signal line S2, a light emitting signal line E, a first power supply line VDD, an initial signal line INIT and a second power supply line VSS).

In an exemplary implementation, the pixel drive circuit may include a first node N1, a second node N2, and a third node N3. Herein, the first node N1 is respectively connected to a first electrode of the third transistor T3, a second electrode of the fourth transistor T4, and a second electrode of the fifth transistor T5. The second node N2 is respectively connected to a second electrode of the first transistor, a first electrode of the second transistor T2, a control electrode of the third transistor T3, and a second terminal of the storage capacitor C. The third node N3 is respectively connected to a second electrode of the second transistor T2, a second electrode of the third transistor T3, and a first electrode of the sixth transistor T6.

In an exemplary implementation, a first terminal of the storage capacitor C is connected to the first power supply line VDD, and the second terminal of the storage capacitor C is connected to the second node N2, i.e., the second terminal of the storage capacitor C is connected to the control electrode of the third transistor T3.

A control electrode of the first transistor T1 is connected to the second scan signal line S2, a first electrode of the first transistor T1 is connected to the initial signal line INIT, and the second electrode of the first transistor is connected to the second node N2. When a scan signal with an on-level is applied to the second scan signal line S2, the first transistor T1 transmits a first initial voltage to the control electrode of the third transistor T3 so as to initialize a charge amount of the control electrode of the third transistor T3.

A control electrode of the second transistor T2 is connected to the first scan signal line S1, the first electrode of the second transistor T2 is connected to the second node N2, and the second electrode of the second transistor T2 is connected to the third node N3. When a scan signal with an on-level is applied to the first scan signal line S1, the second transistor T2 enables the control electrode of the third transistor T3 to be connected to the second electrode of the third transistor T3.

The control electrode of the third transistor T3 is connected to the second node N2, i.e., the control electrode of the third transistor T3 is connected to the second terminal of the storage capacitor C, the first electrode of the third transistor T3 is connected to the first node N1, and the second electrode of the third transistor T3 is connected to the third node N3. The third transistor T3 may be referred to as a drive transistor, and the third transistor T3 determines a magnitude of a drive current flowing between the first power supply line VDD and the second power supply line VSS according to a potential difference between the control electrode and the first electrode of the third transistor T3.

A control electrode of the fourth transistor T4 is connected to the first scan signal line S1, a first electrode of the fourth transistor T4 is connected to the data line D, and the second electrode of the fourth transistor T4 is connected to the first node N1. The fourth transistor T4 may be referred to as a switch transistor, or a scan transistor, etc. When a scan signal with an on-level is applied to the first scan signal line S1, the fourth transistor T4 allows a data voltage of the data line D to be input to the pixel drive circuit.

A control electrode of the fifth transistor T5 is connected to the light emitting signal line E, a first electrode of the fifth transistor T5 is connected to the first power supply line VDD, and the second electrode of the fifth transistor T5 is connected to the first node N1. A control electrode of the sixth transistor T6 is connected to the light emitting signal line E, the first electrode of the sixth transistor T6 is connected to the third node N3, and a second electrode of the sixth transistor T6 is connected to a first electrode of the light emitting device. The fifth transistor T5 and the sixth transistor T6 may be referred to as light emitting transistors. When a light emitting signal with an on-level is applied to the light emitting signal line E, the fifth transistor T5 and the sixth transistor T6 enable the light emitting device to emit light by forming a drive current path between the first power supply line VDD and the second power supply line VSS.

A control electrode of the seventh transistor T7 is connected to the first scan signal line S1, a first electrode of the seventh transistor T7 is connected to the initial signal line INIT, and a second electrode of the seventh transistor T7 is connected to the first electrode of the light emitting device. When a scan signal with an on-level is applied to the first scan signal line S1, the seventh transistor T7 transmits a second initial voltage to the first electrode of the light emitting device so as to initialize a charge amount accumulated in the first electrode of the light emitting device or release a charge amount accumulated in the first electrode of the light emitting device.

In an exemplary implementation, the light emitting device may be an OLED including a first electrode (anode), an organic light emitting layer, and a second electrode (cathode) which are stacked, or may be a QLED including a first electrode (anode), a quantum dot light emitting layer, and a second electrode (cathode) which are stacked.

In an exemplary implementation, a second electrode of the light emitting device is connected to the second power supply line VSS, a signal of the second power supply line VSS is a low-level signal, and a signal of the first power supply line VDD is a high-level signal continuously provided. The first scan signal line S1 is a scan signal line in a pixel drive circuit of a current display row, and the second scan signal line S2 is a scan signal line in a pixel drive circuit of a previous display row. That is, for an n-th display row, the first scan signal line S1 is S(n), and the second scan signal line S2 is S(n−1). The second scan signal line S2 of the current display row and the first scan signal line S1 in the pixel drive circuit of the previous display row are a same signal line, thus signal lines of the display panel may be reduced, so that a narrow bezel of the display panel is achieved.

In an exemplary implementation, the first transistor T1 to the seventh transistor T7 may be P-type transistors or N-type transistors. Use of a same type of transistors in a pixel drive circuit may simplify a process flow, reduce process difficulties of a display panel, and improve a product yield. In some possible implementations, the first transistor T1 to the seventh transistor T7 may include a P-type transistor and an N-type transistor.

In an exemplary implementation, the first transistor T1 to the seventh transistor T7 may be low temperature poly-silicon thin film transistors, or may be oxide thin film transistors, or may be low temperature poly-silicon thin film transistors and oxide thin film transistors. An active layer of a low temperature poly-silicon thin film transistor may be made of Low Temperature Poly-Silicon (LTPS for short), and an active layer of an oxide thin film transistor may be made of an oxide semiconductor (Oxide). The low temperature poly-silicon thin film transistor has advantages such as high migration rate and fast charging. The oxide thin film transistor has advantages such as low drain current. The low temperature poly-silicon thin film transistor and the oxide thin film transistor are integrated on a display substrate to form a Low Temperature Polycrystalline Oxide (LTPO for short) display substrate, so that advantages of the low temperature poly-silicon thin film transistor and the oxide thin film transistor can be utilized, low-frequency drive can be realized, power consumption can be reduced, and display quality can be improved.

FIG. 6 is an operating timing diagram of a pixel drive circuit. An exemplary embodiment of the present disclosure will be described below through an operating process of the pixel drive circuit exemplified in FIG. 5. The pixel drive circuit in FIG. 5 includes seven transistors (a first transistor T1 to a seventh transistor T7) and one storage capacitor C, and the seven transistors are all P-type transistors.

In an exemplary implementation, taking an OLED as example, the operating process of the pixel drive circuit may include the following stages.

In a first stage t1, referred to as a reset stage, a signal of the second scan signal line S2 is a low-level signal, and signals of the first scan signal line S1 and the light emitting signal line E are high-level signals. The signal of the second scan signal line S2 is a low-level signal, so that the first transistor T1 is turned on, and a signal of the initial signal line INIT is provided to a second node N2 to initialize the storage capacitor C to clear an original data voltage in the storage capacitor. The signals of the first scan signal line S1 and the light emitting signal line E are high-level signals, so that the second transistor T2, the fourth transistor T4, the fifth transistor T5, the sixth transistor T6, and the seventh transistor T7 are turned off. An OLED does not emit light in this stage.

In a second stage t2, referred to as a data writing stage or threshold compensating stage, a signal of the first scan signal line S1 is a low-level signal, signals of the second scan signal line S2 and the light emitting signal line E are high-level signals, and the data line D outputs a data voltage. In this stage, a second terminal of the storage capacitor C is at the low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on so that the data voltage output by the data line D is provided to the second node N2 through the first node N1, the turned-on third transistor T3, the third node N3, and the turned-on second transistor T2. A voltage difference between the data voltage output by the data line D and a threshold voltage of the third transistor T3 is charged to the storage capacitor C, where a voltage at the second terminal (the second node N2) of the storage capacitor C is Vd-|Vth|, the data voltage output by the data line D is Vd, and the threshold voltage of the third transistor T3 is Vth. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization to ensure that the OLED does not emit light. The signal of the second scan signal line S2 is the high-level signal, so that the first transistor T1 is turned off. The signal of the light emitting signal line E is the high-level signal, so that the fifth transistor T5 and the sixth transistor T6 are turned off.

In a third stage t3, referred to as a light emitting stage, the signal of the light emitting signal line E is a low-level signal, and the signals of the first scan signal line S1 and the second scan signal line S2 are high-level signals. The signal of the light emitting signal line E is the low-level signal, so that the fifth transistor T5 and the sixth transistor T6 are turned on, and a power voltage output by the first power supply line VDD provides a drive voltage to the first electrode of the OLED through the turned-on fifth transistor T5, the third transistor T3, and the sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata-|Vth|, so the drive current of the third transistor T3 is as follows.

$$I = K * {( Vgs - Vth )}^{2} = K * {[ ( Vdd - Vd + \vert Vth \vert ) - Vth ]}^{2} = K * {[ ( Vdd - Vd ]}^{2}$$

where I is the drive current flowing through the third transistor T3, that is, the drive current for driving the OLED, K is a constant, Vgs is the voltage difference between the gate electrode and the first electrode of the third transistor T3, Vth is the threshold voltage of the third transistor T3, Vd is the data voltage output by the data line D, and Vdd is the power voltage output by the first power supply line VDD.

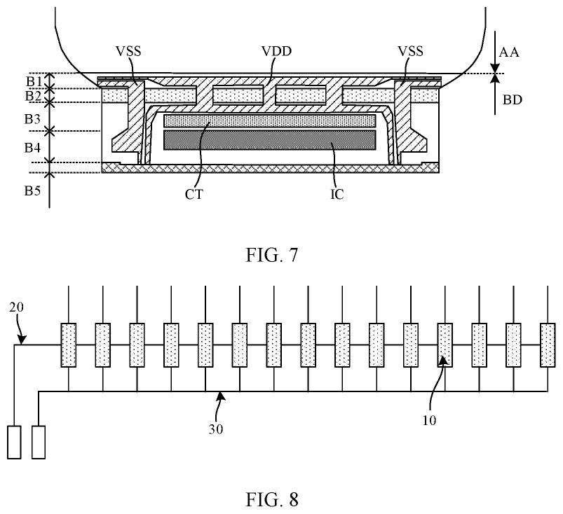

FIG. 7 is a schematic diagram of a planar structure of a bonding area in a display substrate. As shown in FIG. 7, in an exemplary implementation, in a plane parallel to the display substrate, the bonding area BD may be located on a side of a display area AA, and the bonding area BD may include a fan-out region B1, a bending region B2, a detection circuit region B3, a drive chip region B4, and a bonding pin region B5 that are arranged sequentially along a direction away from the display area AA. The first fan-out region B1 at least includes a first power supply line VDD, and a second power supply line VSS and multiple data transmission lines. The multiple data transmission lines are configured to be connected to data lines of the display area AA in a fanout tracing mode. The first power supply line VDD is configured to be connected to a high-level power supply line of the display area AA, and the second power supply line is configured to be connected to a low-level power supply line of an edge area. The bending region may include a composite insulation layer provided with a groove, wherein the groove is configured to allow the bonding area BD to be bent to the back of the display area AA. The detection circuit region B3 may be provided with detection circuits CT for detecting the display substrate, and these detection circuits CT may be connected to corresponding signal lines of the display area. The drive chip region B4 may be provided with an integrated circuit IC, and the integrated circuit IC is connected to a data line of the display area through a data transmission line in the first fan-out region B1 and the integrated circuit IC is configured to generate a drive signal required for driving a sub-pixel, and to supply the drive signal to the data line of the display area. For example, the drive signal may be a data signal that drives a luminance of a sub-pixel. The bonding pin region B5 may be provided with multiple bonding PIN which are configured to be bonded to and connected to an external Flexible Printed Circuit (FPC for short). In an exemplary implementation, the bonding area may include other circuits and signal lines such as an anti-static circuit, a multiplexing circuit (MUX) or the like, which are not limited in the present disclosure.

In an exemplary implementation, the detection circuit region B3 may include a Cell Test (CT for short) that may implement Aging procedure and ET Light-on detections of the display substrate. The preparation process of display substrates requires multiple detections, among which an important detection is a Cell Test (ET for short) Light-on, which is abbreviated as ET Light-on. The ET Light-on test means that before the display substrate is not bound with a drive chip (IC) and a flexible circuit board (FPC), a detection signal is input to the display substrate to make its pixels present color, and a defect detection apparatus checks whether each pixel is in good condition to confirm whether the display substrate has defects. Because there are situations, for example, the interface not stable in the prepared light emitting devices, the aging procedure is a necessary process before the display apparatus is delivered. By lighting the light emitting devices with a certain current for a period of time, the interface-not-stable can be aged off, the brightness attenuation of the light emitting devices can be reduced, and the life of the light emitting devices can be prolonged.

FIG. 8 is an equivalent circuit diagram of a detection circuit. As shown in FIG. 8, the detection circuit may include at least multiple detection sub-units 10, a control line 20 and a signal line 30. Each detection sub-unit 10 may include a control end, an input end and an output end. One end of the control line 20 is connected correspondingly to a pin in the bonding pin region, and the other end of the control line 20 may be connected correspondingly to control ends of the multiple detection sub-units 10. One end of the signal line 30 is connected correspondingly to a pin in the bonding pin region, and the other end of the signal line 30 may be connected correspondingly to input ends of the multiple detection sub-units 10. The output ends of the multiple detection sub-units 10 may be connected correspondingly to multiple data lines in the display area, and the detection sub-units 10 are configured to output a signal output from the signal line 30 to the data lines in the display area under the control of the control line 20, so as to achieve an aging procedure and a Light-on detection of the display substrate.

In an exemplary implementations, a process of an aging treatment of the detection circuit is as follows: before the display substrate is bound to the drive chip (IC) and the flexible printed circuit (FPC), an external apparatus is connected to a pin in the bonding area, wherein the external apparatus outputs a control signal and an aging voltage signal to the signal line through the pin, the control signal controls multiple detection sub-units to be turned on, and the detection sub-units output the aging voltage signal to multiple data lines in the display area and perform aging procedure for red sub-pixels, blue sub-pixels and green sub-pixels respectively.

In a Light-on detection of a display substrate, a vertical line ripple (Mura) defect appears on the display substrate. A research shows that a main reason for the Mura defect of display substrate is that a same aging voltage is used for the whole display area in the existing aging procedure. Further research shows that for a display substrate using FDC technology, an anode area of a second display area is usually reduced in the existing design to improve transmittance of the second display area, but this design makes the life characteristics of the light emitting devices in the first display area different from those in the second display area. Since the first display area and the second display area use the same aging voltage, brightness characteristic of the light emitting devices after aging in the first display area is different from that of the light emitting devices after aging in the second display area, so that the brightness of the first display area is different from that of the second display area when the Light-on detection is performed, such that the first display area presents the Mura defect.

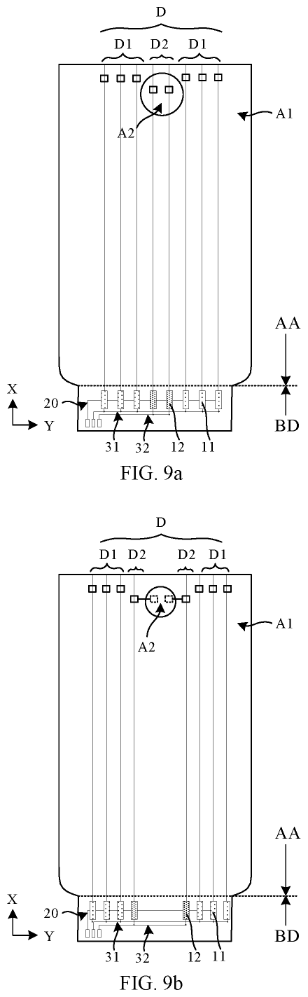

FIG. 9a and FIG. 9b are equivalent circuit diagrams of a detection circuit of an exemplary embodiment of the present disclosure, wherein in a display substrate illustrated by FIG. 9a, a second display area A2 is provided with a pixel drive circuit and a light emitting device (the pixel drive circuit being built in), and in a display substrate illustrated by FIG. 9b, a second display area A2 is provided with a light emitting device only (the pixel drive circuit being external). In an exemplary implementation, the display substrate may include a display area AA and a bonding area BD located on a side of the display area AA. The display area AA may include a first display area A1 and a second display area A2, and the first display area A1 which is configured to perform image display may at least partially surround the second display area A2 which is configured to display an image and transmit light.

As shown in FIG. 9a, in an exemplary implementation, the first display area A1 may include multiple first sub-pixels, and a first sub-pixel may include a first pixel drive circuit and a first light emitting device. The second display area A2 may include multiple second sub-pixels, and a second sub-pixel may include a second pixel drive circuit and a second light emitting device, both of which are arranged in the second display area A2. The multiple first sub-pixels in the first display area A1 are regularly arranged to form multiple first pixel rows and multiple first pixel columns, and the multiple second sub-pixels in the second display area A2 may be regularly arranged to form multiple second pixel rows and multiple second pixel columns. The display area further includes multiple data lines D, wherein the multiple data lines D may include multiple first data lines D1 and multiple second data lines D2. The multiple first data lines D1 and the multiple second data lines D2 may extend along a first direction X, and are sequentially arranged at set intervals along a second direction Y. Each first data line D1 is electrically connected to first pixel drive circuits of multiple first sub-pixels of one pixel column in the first display area A1, and each second data line D2 is electrically connected to second pixel drive circuits of multiple second sub-pixels of one pixel column in the second display area A2, and is connected to first pixel drive circuits of a part of the first sub-pixels. In an exemplary implementation, the first direction X may be a column direction of the display substrate, the second direction Y may be a row direction of the display substrate, and the first direction X and the second direction Y may be perpendicular to each other.

As shown in FIG. 9b, in an exemplary implementation, the first display area A1 may include multiple first sub-pixels, wherein a first sub-pixel may include a first pixel drive circuit and a first light emitting device. The second display area A2 may include multiple second sub-pixels, wherein the second sub-pixel includes a second light emitting device and a second pixel drive circuit. The second light emitting device of the second sub-pixel is arranged in the second display area A2, the second pixel drive circuit of the second sub-pixel is arranged in the first display area A1, and the second light emitting device is connected to the second pixel drive circuit through an anode connection line. The display area further includes multiple data lines D, wherein the multiple data lines D may include multiple first data lines D1 and multiple second data lines D2. The multiple first data lines D1 and the multiple second data lines D2 may extend along the first direction X and are sequentially arranged at set intervals along the second direction Y. Each first data line D1 is connected to first pixel drive circuits of multiple first sub-pixels in one pixel column, and each second data line D2 is connected to second pixel drive circuits of multiple second sub-pixels in one pixel column and is connected to first pixel drive circuits of a part of the first sub-pixels.

In an exemplary implementation, the detection circuit may be arranged in the bonding area BD, and at least include multiple first detection sub-units 11, multiple second detection sub-units 12, at least one control line 20, at least one first signal line 31, and at least one second signal line 32.

In an exemplary implementation, the multiple first detection sub-units 11 and the multiple second detection sub-units 12 may each include a control end, an input end and an output end. The multiple first detection sub-units 11 and the multiple second detection sub-units 12 may be sequentially arranged at set intervals along the second direction Y, positions of the multiple first detection sub-units 11 may be in one-to-one correspondence to positions of the multiple first data lines D1 in the display area, and positions of the multiple second detection sub-units 12 may be in one-to-one correspondence to positions of the multiple second data lines D2 in the display area.

In an exemplary implementation, one end of the control line 20 is connected correspondingly to a control pin of the bonding pin region, the other end of the control line 20 is connected simultaneously to control ends of the multiple first detection sub-units 11 and the multiple second detection sub-units 12, and the control line 20 is configured to control multiple first detection sub-units 11 and multiple second detection sub-units 12 to be turned on or turned off.

In an exemplary implementation, one end of the first signal line 31 is connected correspondingly to a first signal pin in the bonding pin region, the other end of the first signal line 31 is connected to input ends of the multiple first detection sub-units 11. Output ends of the multiple first detection sub-units 11 are connected correspondingly to the multiple first data lines D1 of the display area, the first signal line 31 is configured to receive a first signal from an external apparatus through the first signal pin, and the first detection sub-units 11 are configured to output the first signal to the first data lines D1 of the display area to perform an aging treatment or a Light-on detection on the first sub-pixels in the first display area.

In an exemplary implementation, one end of the second signal line 32 is connected correspondingly to a second signal pin in the bonding pin region, the other end of the second signal line 32 is connected to input ends of the multiple second detection sub-units 12. Output ends of the multiple second detection sub-units 12 are connected correspondingly to the multiple second data lines D2 of the display area, the second signal line 32 is configured to receive a second signal from an external apparatus through the second signal pin, and the second detection sub-units 12 are configured to output the second signal to the second data lines D2 of the display area to perform an aging treatment or a Light-on detection on the second sub-pixels in the second display area.

In an exemplary implementation, an operating process of the aging treatment of the detection circuit of this exemplary embodiment is as follows: the external apparatus is connected to the control pin, the first signal pin and the second signal pin of the bonding area, and the external apparatus outputs a control signal through the control pin, a first aging voltage signal through the first signal pin, and a second aging voltage signal through the second signal pin, wherein the first aging voltage is different from the second aging voltage. A control signal transmitted by the control line 20 controls multiple first detection sub-units 11 and multiple second detection sub-units 12 to be turned on. The multiple first detection sub-units 11 which are turned on output the first aging voltage signal transmitted by the first signal lines 31 to multiple first data lines D1 in the display area respectively. An aging treatment is performed on the first sub-pixels in the first display area by using the first aging voltage signal. The multiple second detection sub-units 12 which are turned on output the second aging voltage signal transmitted by the second signal lines 32 to multiple second data lines D2 in the display area respectively. An aging treatment is performed on the second sub-pixels in the second display area by using the second aging voltage signal.

The exemplary embodiment of the present disclosure provides a technical scheme of aging by areas, an aging treatment is performed on the first sub-pixels of the first display area by using the first aging voltage, and an aging treatment is performed on the second sub-pixels of the second display area by using the second aging voltage, wherein the first aging voltage is different from the second aging voltage. Since different aging voltages are used for the first display area and the second display area, brightness characteristic of the light emitting devices after aging in the first display area is substantially the same as that of the light emitting devices after aging in the second display area, so that a brightness difference between the first display area and the second display area can be eliminated, and a Mura defect in the display area can be effectively avoided.

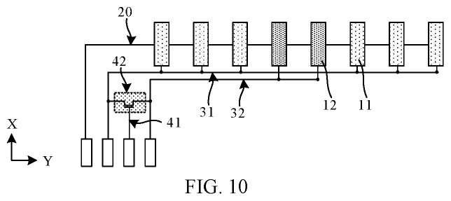

FIG. 10 is an equivalent circuit diagram of another detection circuit according to an exemplary embodiment of the present disclosure. As shown in FIG. 10, the detection circuit may include multiple first detection sub-units 11, multiple second detection sub-units 12, at least one control line 20, at least one first signal line 31, at least one second signal line 32, at least one switching control line 41, and at least one switching unit 42. A connection structure between the at least one control line 20, the at least one first signal line 31 and the at least one second signal line 32 to the multiple first detection sub-units 11 and the multiple second detection sub-units 12 is substantially the same as the structure shown in FIG. 9a.

In an exemplary implementation, the switching unit 42 may include a switching control end, a first switching end and a second switching end. One end of the switching control line 41 is connected to a switching pin in the bonding pin region, the other end of the switching control line 41 is connected to the switching control end of the switching unit 42. The first switching end of the switching unit 42 is connected to a first signal line 31, the second switching end of the switching unit 42 is connected to a second signal line 32. The switching control line 41 is configured to receive an external switching signal through a switching pin, and the switching unit 42 is configured to isolate or turn on the first signal line 31 and the second signal line 32 under the control of the switching control line 41. When the first signal line 31 and the second signal line 32 are isolated from each other, the first signal line 31 and the second signal line 32 output different aging voltage signals, and when the first signal line 31 and the second signal line 32 are turned on, the first signal line 31 and the second signal line 32 output a same Light-on voltage signal.

In an exemplary implementation, the switching unit 42 may include a switching transistor, wherein a control electrode of the switching transistor is connected to the switching control line 41, a first electrode of the switching transistor is connected to the first signal line 31, and a second electrode of the switching transistor is connected to the second signal line 32.

In an exemplary implementation, an operating process of the aging procedure performed by the detection circuit of this exemplary embodiment is as follows: the external apparatus outputs a control signal through a control pin, outputs a disconnection signal through a switching pin, outputs a first aging voltage signal through a first signal pin, and outputs a second aging voltage signal through a second signal pin. A control signal transmitted by the control line 20 controls multiple first detection sub-units 11 and multiple second detection sub-units 12 to be turned on, and a disconnection signal transmitted by the switching control line 41 controls the switching unit 42 to be turned off so that the first signal line 31 and the second signal line 32 are isolated from each other. Multiple first detection sub-units 11 that are turned on output the first aging voltage signal transmitted by the first signal lines 31 to multiple first data lines D1 in the display area respectively, and perform aging treatment on the first sub-pixels in the first display area by using the first aging voltage signals. Multiple second detection sub-units 12 that are turned on output the second aging voltage signal transmitted by the second signal line 32 to multiple second data lines D2 in the display area respectively, and perform aging treatment on the second sub-pixels in the second display area by using the second aging voltage signal, wherein the aging voltages in the first display area and the second display area are different.

In an exemplary implementation, an operating process of Light-on detection by the detection circuit of this exemplary embodiment is as follows: an external apparatus outputs a control signal through a control pin, outputs a turn-on signal through a switching pin, outputs a Light-on voltage signal through a first signal pin or outputs a Light-on voltage signal through a second signal pin. A control signal transmitted by the control line 20 controls multiple first detection sub-units 11 and multiple second detection sub-units 12 to be turned on, and a turn-on signal transmitted by the switching control line 41 controls the switching unit 42 to be turned on, such that the first signal line 31 is communicated with the second signal line 32, and the first signal line 31 and the second signal line 32 transmit the same Light-on voltage signal. Multiple first detection sub-units 11 and multiple second detection sub-units 12 that are turned on output the Light-on voltage signal to multiple first data lines D1 and multiple second data lines D2 in the display area respectively, and Light-on detection is performed on sub-pixels in the first display area and the second display area using the same Light-on voltage signal.

An exemplary embodiment of the present disclosure provides a technical scheme of aging by areas and overall Light-on. when an aging procedure is performed, the first signal line and the second signal line are partitioned by a switching unit provided, an aging treatment is performed on a first sub-pixel in the first display area by using a first aging voltage, and an aging treatment is performed on a second sub-pixel of the second display area by using a second aging voltage, so that the aging voltages in the first display area and the second display area are different. When the Light-on detection is performed, the first signal line and the second signal line are turned on by the switching unit provided, and the Light-on detection is performed by using the same Light-on voltage for the first sub-pixel in the first display area and the second sub-pixel in the second display area. Since different aging voltages are used for the first display area and the second display area, brightness characteristic of the light emitting devices after aging in the first display area is substantially the same as that of the light emitting devices after aging in the second display area, so that a brightness difference between the first display area and the second display area can be eliminated, and a Mura defect can be effectively avoided. Since the same Light-on voltage is used for the first display area and the second display area, uniformity of picture thus can be ensured.

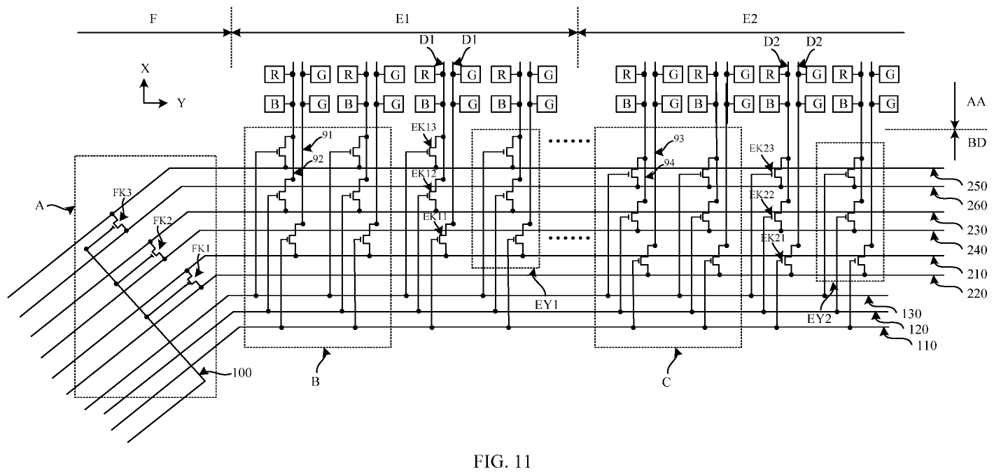

FIG. 11 is an equivalent circuit diagram of another detection circuit according to an exemplary embodiment of the present disclosure. As shown in FIG. 11, the display area AA may include multiple first data lines D1 and multiple second data lines D2. The first data lines D1 are connected correspondingly to first sub-pixels in the first display area, the second data lines D2 connected correspondingly to second sub-pixels in the second display area, and the bonding area BD may include a detection circuit. In an exemplary implementation, the detection circuit may include a first detection unit E1, a second detection unit E2, a switching unit F, and multiple signal lines. The first detection unit E1 may be located on a side of the switching unit F in the second direction Y, the second detection unit E2 may be located on a side of the first detection unit E1 in the second direction Y, and the first detection unit E1 may be provided on a side of the second detection unit E2 in the second direction Y.

In an exemplary implementation, the multiple signal lines may at least include a switching control line 100, a first control line 110, a second control line 120, a third control line 130, a first detection line 210, a second detection line 220, a third detection line 230, a fourth detection line 240, a fifth detection line 250, a sixth detection line 260. First ends of the signal lines described above are connected correspondingly to pins in the bonding pin region, and second ends of the signal lines extends to a detection circuit region where the detection circuit is located, and are connected to the first detection unit E1, the second detection unit E2 and a the switching unit F.

In an exemplary implementation, the first detection unit E1 may include multiple first detection sub-units EY1 arranged sequentially at set intervals along the second direction Y, and positions of the multiple first detection sub-units EY1 may correspond to positions of multiple first data lines D1 in the display area. Each of the first detection sub-units EY1 may include an eleventh switch unit EK11, a twelfth switch unit EK12, and a thirteenth switch unit EK13 arranged sequentially at set intervals along the first direction X, and each of the switch units may include a control end, an input end, and an output end.

In an exemplary implementation, a control end of the eleventh switch unit EK11 is connected to the first control line 110, an input end of the eleventh switch unit EK11 is connected to the first detection line 210, and an output end of the eleventh switch unit EK11 is connected to a first data line D1 connected to a G sub-pixel in the display area through a first transmission line 91. The eleventh switch unit EK11 is configured to transmit a first signal transmitted by the first detection line 210 to the first data line D1 connected to the G sub-pixel under the control of the first control line 110.

In an exemplary implementation, a control end of the twelfth switch unit EK12 is connected to the second control line 120, an input end of the twelfth switch unit EK12 is connected to the third detection line 230, and an output end of the twelfth switch unit EK12 is connected to a first data line D1 connected to a B sub-pixel in the display area through a second transmission line 92. The twelfth switch unit EK12 is configured to transmit a third signal transmitted by the third detection line 230 to the first data line D1 connected to the B sub-pixel under the control of the second control line 120.

In an exemplary implementation, a control end of the thirteenth switch unit EK13 is connected to the third control line 130, an input end of the thirteenth switch unit EK13 is connected to the fifth detection line 250, and an output end of the thirteenth switch unit EK13 is connected to a first data line D1 connected to a R sub-pixel in the display area through a second transmission line 92. The thirteenth switch unit EK13 is configured to transmit a fifth signal transmitted by the fifth detection line 250 to the first data line D1 connected to the R sub-pixel under the control of the third control line 130.

In an exemplary implementation, the second detection unit E2 may include multiple second detection sub-units EY2 arranged sequentially at set intervals along the second direction Y, and positions of the multiple second detection sub-units EY2 may correspond to positions of multiple second data lines D2 in the display area. Each of the second detection sub-units EY2 may include an twenty-first switch unit EK21, a twenty-second switch unit EK22, and a twenty-third switch unit EK23 arranged sequentially at set intervals along the first direction X, and each of the switch units may include a control end, an input end, and an output end.

In an exemplary implementation, a control end of the twenty-first switch unit EK21 is connected to the first control line 110, an input end of the twenty-first switch unit EK21 is connected to a second detection line 220, and an output end of the twenty-first switch unit EK21 is connected to a second data line D2 connected to a G sub-pixel in the display area through a third transmission line 93. The twenty-first switch unit EK21 is configured to transmit a second signal transmitted by a second detection line 220 to the second data line D2 connected to the G sub-pixels under the control of the first control line 110.

In an exemplary implementation, a control end of the twenty-second switch unit EK22 is connected to the second control line 120, an input end of the twenty-second switch unit EK22 is connected to a fourth detection line 240, and an output end of the twenty-second switch unit EK22 is connected to a second data line D2 connected to a B sub-pixel in the display area through a fourth transmission line 94. The twenty-second switch unit EK22 is configured to transmit a fourth signal transmitted by the fourth detection line 240 to the second data line D2 connected to the B sub-pixel under the control of the second control line 120.

In an exemplary implementation, a control end of the twenty-third switch unit EK23 is connected to a third control line 130, an input end of the twenty-third switch unit EK23 is connected to a sixth detection line 260, and an output end of the twenty-third switch unit EK23 is connected to a second data line D2 connected to a R sub-pixel in the display area through a fourth transmission line 94. The twenty-third switch unit EK23 is configured to transmit a sixth signal transmitted by the sixth detection line 260 to the second data line D2 connected to the R sub-pixel under the control of the third control line 130.

In an exemplary implementation, the switching unit F may include a first switching sub-unit FK1, a second switching sub-unit FK2, and a third switching sub-unit FK3, each of which may each include a control electrode, a first electrode, and a second electrode.

In an exemplary implementation, a control electrode of the first switching sub-unit FK1 is connected to the switching control line 100, a first electrode of the first switching sub-unit FK1 is connected to the first detection line 210, and a second electrode of the first switching sub-unit FK1 is connected to the second detection line 220. The first switching sub-unit FK1 is configured to isolate or turn on the first detection line 210 and the second detection line 220 under the control of the switching control line 100. When the first detection line 210 and the second detection line 220 are isolated from each other, the first detection line 210 and the second detection line 220 output different aging voltage signals, and when the first detection line 210 and the second detection line 220 are turned on, the first detection line 210 and the second detection line 220 output a same Light-on voltage signal.

In an exemplary implementation, a control electrode of the second switching sub-unit FK2 is connected to the switching control line 100, a first electrode of the second switching sub-unit FK2 is connected to the third detection line 230, and a second electrode of the second switching sub-unit FK2 is connected to the fourth detection line 240. The second switching sub-unit FK2 is configured to isolate or turn on the third detection line 230 and the fourth detection line 240 under the control of the switching control line 100. When the third detection line 230 and the fourth detection line 240 are isolated from each other, the third detection line 230 and the fourth detection line 240 output different aging voltage signals, and when the third detection line 230 and the fourth detection line 240 are turned on, the third detection line 230 and the fourth detection line 240 output a same Light-on voltage signal.

In an exemplary implementation, a control electrode of the third switching sub-unit FK3 is connected to the switching control line 100, a first electrode of the third switching sub-unit FK3 is connected to the fifth detection line 250, and a second electrode of the third switching sub-unit FK3 is connected to the sixth detection line 260. The third switching sub-unit FK3 is configured to isolate or turn on the fifth detection line 250 and the sixth detection line 260 under the control of the switching control line 100. When the fifth detection line 250 and the sixth detection line 260 are isolated from each other, the fifth detection line 250 and the sixth detection line 260 output different aging voltage signals, and when the fifth detection line 250 and the sixth detection line 260 are turned on, the fifth detection line 250 and the sixth detection line 260 output a same Light-on voltage signal.

In an exemplary implementation, an operating process of an aging procedure performed by a detection circuit of this exemplary embodiment is as follows:
when an aging procedure is performed on a G sub-pixel in the display area, an external apparatus causes the switching control line 100 to output a switching control signal, the first control line 110 to output a first control signal, the first detection line 210 to output a first aging voltage signal, and the second detection line 220 to output a second aging voltage signal through multiple pins, wherein the switching control signal is a turn-off signal, the first control signal is a turn-on signal, and the first aging voltage signal is different from the second aging voltage signal. The first switching sub-unit FK1 is turned off by the turn-off signal output from the switching control line 100, and the first detection line 210 and the second detection line 220 are isolated from each other. An eleventh switch unit EK11 and a twenty-first switch unit EK21 are turned on by the turn-on signal output from the first control line 110 respectively. An aging treatment is performed on a G sub-pixel in a first display area in a way that the first aging voltage signal output from the first detection line 210 is output to a first data line D1 connected to a G sub-pixel in the display area through the eleventh switch unit EK11 which is turned on, and an aging treatment is performed on a G sub-pixel in a second display area in a way that the second aging voltage signal output from the second detection line 220 is output to a second data line D1 connected to a G sub-pixel in the display area through the twenty-first switch unit EK21 which is turned on, wherein the aging voltages in the first display area and the second display area are different.

When an aging procedure is performed on a B sub-pixel in the display area, the external apparatus causes the switching control line 100 to output a switching control signal, the second control line 120 to output a second control signal, the third detection line 230 to output a third aging voltage signal, and the fourth detection line 240 to output a fourth aging voltage signal through multiple pins, wherein the switching control signal is a turn-off signal, the second control signal is a turn-on signal, and the third aging voltage signal is different from the fourth aging voltage signal. The second switching sub-unit FK2 is turned off by the turn-off signal output from the switching control line 100, and the third detection line 230 and the fourth detection line 240 are isolated from each other. An twelfth switch unit EK12 and a twenty-second switch unit EK22 are turned on by the turn-on signal output from the second control line 120 respectively. An aging treatment is performed on a B sub-pixel in the first display area in a way that the third aging voltage signal output from the third detection line 230 is output to a first data line D1 connected to a B sub-pixel in the display area through the twelfth switch unit EK12 which is turned on, and an aging treatment is performed on a B sub-pixel in the second display area in a way that the fourth aging voltage signal output from the fourth detection line 240 is output to a second data line D2 connected to a B sub-pixel in the display area through the twenty-second switch unit EK22 which is turned on, wherein the aging voltages in the first display area and the second display area are different.

When an aging procedure is performed on a R sub-pixel in the display area, the external apparatus causes the switching control line 100 to output a switching control signal, the third control line 130 to output a third control signal, the fifth detection line 250 to output a fifth aging voltage signal, and the sixth detection line 260 to output a sixth aging voltage signal through multiple pins, wherein the switching control signal is a turn-off signal, the third control signal is a turn-on signal, and the fifth aging voltage signal is different from the sixth aging voltage signal. The third switching sub-unit FK3 is turned off by the turn-off signal output from the switching control line 100, and the fifth detection line 250 and the sixth detection line 260 are isolated from each other. A thirteenth switch unit EK13 and a twenty-third switch unit EK23 are turned on by the turn-on signal output from the third control line 130 respectively. An aging treatment is performed on a R sub-pixel in the first display area in a way that the fifth aging voltage signal output from the fifth detection line 250 is output to a first data line D1 connected to a R sub-pixel in the display area through the thirteenth switch unit EK13 which is turned on, and an aging treatment is performed on a R sub-pixel in the second display area in a way that the sixth aging voltage signal output from the sixth detection line 260 is output to a second data line D2 connected to the R sub-pixel in the display area through the twenty-third switch unit EK23 which is turned on, wherein the aging voltages in the first display area and the second display area are different.

In an exemplary implementation, an operating process of a Light-on detection performed by a detection circuit of this exemplary embodiment is as follows:

When a Light-on detection is performed on a G sub-pixel in the display area, an external apparatus causes the switching control line 100 to output a switching control signal, the first control line 110 to output a first control signal, and the first detection line 210 or the second detection line 220 to output a first Light-on voltage signal through multiple pins, wherein the switching control signal is a turn-on signal and the first control signal is a turn-on signal. The first switching sub-unit FK1 is turned on by the turn-on signal output from the switching control line 100, and the first detection line 210 and the second detection line 220 are connected to each other, so that the first detection line 210 and the second detection line 220 output a same first Light-on voltage signal. A turn-on signal output from the first control line 110 turns on an eleventh switch unit EK11 and a twenty-first switch unit EK21 respectively. First Light-on voltage signals output from the first detection line 210 and the second detection line 220 are respectively output to a first data line D1 connected to a G sub-pixel and a second data line D2 connected to a G sub-pixel in the display area through the eleventh switch unit EK11 and the twenty-first switch unit EK21 which are turned on, and a Light-on treatment is performed on the G sub-pixels in the first display area and the second display area by using a same Light-on voltage.

When a Light-on detection is performed on a B sub-pixel in the display area, the external apparatus causes the switching control line 100 to output a switching control signal, the second control line 120 to output a second control signal, and the third detection line 230 or the fourth detection line 240 to output a second Light-on voltage signal through multiple pins, wherein the switching control signal is a turn-on signal and the second control signal is a turn-on signal. The second switching sub-unit FK2 is turned on by the turn-on signal output from the switching control line 100, and the third detection line 230 and the fourth detection line 240 are connected to each other, so that the third detection line 230 and the fourth detection line 240 output a same second Light-on voltage signal. The turn-on signal output from the second control line 120 turns on an twelfth switch unit EK12 and a twenty-second switch unit EK22 respectively. Second Light-on voltage signals output from the third detection line 230 and the fourth detection line 240 are respectively output to a first data line D1 connected to a B sub-pixel and a second data line D2 connected to a B sub-pixel in the display area through the twelfth switch unit EK12 and the twenty-second switch unit EK22 which are turned on, and a Light-on treatment is performed on the B sub-pixels in the first display area and the second display area by using a same Light-on voltage.

When a Light-on detection is performed on a G sub-pixel in the display area, the external apparatus causes the switching control line 100 to output a switching control signal, the third control line 130 to output a third control signal, and the fifth detection line 250 or the sixth detection line 260 to output a third Light-on voltage signal through multiple pins, wherein the switching control signal is a turn-on signal and the third control signal is a turn-on signal. The third switching sub-unit FK3 is turned on by the turn-on signal output from the switching control line 100, and the fifth detection line 250 and the sixth detection line 260 are connected to each other, so that the fifth detection line 250 and the sixth detection line 260 output a same third Light-on voltage signal. The turn-on signal output from the third control line 130 turns on the thirteen switch unit EK13 and the twenty-third switch unit EK23 respectively. Third Light-on voltage signals output from the fifth detection line 250 and the sixth detection line 260 are output to a first data line D1 connected to a R sub-pixel and a second data line D2 connected to the R sub-pixel in the display area through the thirteen switch unit EK13 and the twenty-third switch unit EK23 which are turned on respectively, and a Light-on treatment is performed on the R sub-pixels in the first display area and the second display area by using a same Light-on voltage.

In an exemplary implementation, the first switching sub-unit FK1 may include two first transistors connected in series. Control electrodes of the two first transistors are connected to the switching control line, a first electrode of one first transistor is connected to the first detection line, a second electrode of the other first transistor is connected to the second detection line, and a second electrode of the one first transistor and a first electrode of the other first transistor are connected to each other.

In an exemplary implementation, the second switching sub-unit FK2 may include two second transistors connected in series. Control electrodes of the two second transistors are connected to the switching control line, a first electrode of one second transistor is connected to the third detection line, a second electrode of the other second transistor is connected to the fourth detection line, and a second electrode of the one second transistor and a first electrode of the other second transistor are connected to each other.

In an exemplary implementation, the third switching sub-unit FK3 may include two third transistors connected in series. Control electrodes of the two third transistors are connected to the switching control line, a first electrode of one third transistor is connected to the fifth detection line, a second electrode of the other third transistor is connected to the sixth detection line, and a second electrode of the one third transistor and a first electrode of the other third transistor are connected to each other.

In an exemplary implementation, the eleventh switch unit EK11 may include at least one eleventh transistor. A control electrode of the eleventh transistor is connected to the first control line, the first electrode of the eleventh transistor is connected to the first detection line, and a second electrode of the eleventh transistor is connected to a first data line connected to a G sub-pixel in the first display area.

In an exemplary implementation, the twelfth switch unit EK12 may include at least one twelfth transistor and at least one thirteenth transistor. Control electrodes of the twelfth transistor and the thirteenth transistor are connected to the second control line, first electrodes of the twelfth transistor and the thirteenth transistor are connected to the third detection line, and second electrodes of the twelfth transistor and the thirteenth transistor are connected to a first data line connected to a B sub-pixel in the first display area.

In an exemplary implementation, the thirteenth switch unit EK13 may include at least one fourteenth transistor and at least one fifteenth transistor. Control electrodes of the fourteenth transistor and the fifteenth transistor are connected to the third control line, first electrodes of the fourteenth transistor and the fifteenth transistor are connected to the fifth detection line, and second electrodes of the fourteenth transistor and the fifteenth transistor are connected to a first data line connected to a R sub-pixel in the first display area.

In an exemplary implementation, the twenty-first switch unit EK21 may include at least one twenty-first transistor. A control electrode of the twenty-first transistor is connected to the first control line, a first electrode of the twenty-first transistor is connected to the second detection line, and a second electrode of the twenty-first transistor is connected to a second data line connected to a G sub-pixel in the second display area.

In an exemplary implementation, the twenty-second switch unit EK22 may include at least one twenty-second transistor and at least one twenty-third transistor. Control electrodes of the twenty-second transistor and the twenty-third transistor are connected to the second control line, first electrodes of the twenty-second transistor and the twenty-third transistor are connected to the fourth detection line, and second electrodes of the twenty-second transistor and the twenty-third transistor are connected to a second data line connected to a B sub-pixel in the second display area.

In an exemplary implementation, the twenty-third switch unit EK23 may include at least one twenty-fourth transistor and at least one twenty-fifth transistor. Control electrodes of the twenty-fourth transistor and the twenty-fifth transistor are connected to the third control line, first electrodes of the twenty-fourth transistor and the twenty-fifth transistor are connected to the sixth detection line, and second electrodes of the twenty-fourth transistor and the twenty-fifth transistor are connected to a second data line connected to a R sub-pixel in the second display area.

In an exemplary implementation, in a plane perpendicular to the display substrate, the detection circuit may include:
a first insulation layer arranged on a base substrate;
a semiconductor layer arranged on the first insulation layer, wherein the semiconductor layer may include active layers of multiple transistors in a switch unit, active layers of multiple transistors in a first detection sub-unit, and active layers of multiple transistors in a second detection sub-unit;
a second insulation layer covering the semiconductor layer, and a first conductive layer arranged on the second insulation layer, wherein the first conductive layer may include gate electrodes of multiple transistors in the switch unit, gate electrodes of multiple transistors in the first detection sub-unit, and gate electrodes of multiple transistors in the second detection sub-unit;
a third insulation layer covering the first conductive layer, and a second conductive layer arranged on the third insulation layer;
a fourth insulation layer covering the second conductive layer, wherein the fourth insulation layer is provided with multiple vias; and
a third conductive layer arranged on the fourth insulation layer, wherein the third conductive layer may include control lines, first signal lines, and second signal lines.

In an exemplary implementation, the control lines include a first control line, a second control line and a third control line. At least one of the first control line, the second control line and the third control line includes a control lead-out line and a control extension line. The control lead-out line and the control extension line are connected through a signal connection line arranged in the first conductive layer, and the control lead-out line and the control extension line are arranged in the third conductive layer.

In an exemplary implementation, the first signal lines include a first detection line, a third detection line and a fifth detection line, and the second signal lines include a second detection line, a fourth detection line and a sixth detection line. At least one of the first detection line, the second detection line, the third detection line, the fourth detection line, the fifth detection line and the sixth detection line includes a detection lead-out line and a detection extension line. The detection lead-out line and the detection extension line are connected through a signal connection line arranged in the first conductive layer, and the detection lead-out line and the detection extension line are arranged in the third conductive layer.

In an exemplary implementation, the first conductive layer further includes a switching connection line, and the third conductive layer further includes a switching control line. The switching connection line is connected to the switching control line through a via, and the switching connection line and gate electrodes of multiple transistors in the switching unit are connected to each other to form an integral structure.

In an exemplary implementation, the first detection sub-unit includes a first transmission line and a second transmission. The first transmission line is connected to a first data line connected to a first color sub-pixel in the first display area and the second transmission line is connected to a first data line connected to a second color sub-pixel and a third color sub-pixel in the first display area. The first transmission line is arranged in the first conductive layer, and the second transmission line is arranged in the second conductive layer.

In an exemplary implementation, a twenty-first connection block and a twenty-second connection block are provided on the second transmission line. The twenty-first connection block is connected to a twelfth active layer and a thirteenth active layer in the first detection sub-unit through a twelfth connection electrode, and the twenty-first connection block is arranged between the twelfth active layer and the thirteenth active layer. The twenty-second connection block is connected to a fourteenth active layer and a fifteenth active layer in the first detection sub-unit through a thirteenth connection electrode, and the twenty-second connection block is arranged between the fourteenth active layer and the fifteenth active layer.

In an exemplary implementation, the twelfth connection electrode and the thirteenth connection electrode are arranged in the third conductive layer.

In an exemplary implementation, the second detection sub-unit includes a third transmission line a fourth transmission line. The third transmission line is connected to a second data line connected to a first color sub-pixel in the second display area, and the fourth transmission line is connected to a second data line connected to a second color sub-pixel and a third color sub-pixel in the second display area.; The third transmission line is arranged in the first conductive layer, and the fourth transmission line is arranged in the second conductive layer.

In an exemplary implementation, a forty-first connection block, a forty-second connection block, a forty-third connection block and a forty-fourth connection block are provided on the fourth transmission line. The forty-first connection block is connected to a twenty-second active layer in the second detection sub-unit through a twenty-second connection electrode, and the forty-first connection block is arranged on a side of the twenty-second active layer in the first direction. The forty-second connection block is connected to a twenty-third active layer in the second detection sub-unit through a twenty-third connection electrode, and the forty-second connection block is arranged on a side of the twenty-third active layer in a direction opposite to the first direction. The forty-third connection block is connected to a twenty-fourth active layer in the second detection sub-unit through a twenty-fourth connection electrode, and the forty-third connection block is arranged on a side of the twenty-fourth active layer in the first direction. The forty-fourth connection block is connected to a twenty-fifth active layer in the second detection sub-unit through a twenty-fifth connection electrode, and the forty-fourth connection block is arranged on a side of the twenty-fifth active layer in the direction opposite to the first direction. The first direction is an extension direction of the fourth transmission line.

In an exemplary implementation, the twenty-second connection electrode, the twenty-third connection electrode, the twenty-fourth connection electrode, and the twenty-fifth connection electrode are arranged in the third conductive layer.

Exemplary description is made below through a preparation process of the detection circuit. A “patterning process” mentioned in the present disclosure includes coating with a photoresist, mask exposure, development, etching, photoresist stripping, and other treatments for a metal material, an inorganic material, or a transparent conductive material, and includes coating with an organic material, mask exposure, development, and other treatments for an organic material. Deposition may be any one or more of sputtering, evaporation, and chemical vapor deposition. Coating may be any one or more of spray coating, spin coating, and ink-jet printing. Etching may be any one or more of dry etching and wet etching, which is not limited in present disclosure. A “thin film” refers to a layer of thin film made of a material on a base substrate through a process such as deposition, coating, etc. If the “thin film” does not need a patterning process in an entire preparation process, the “thin film” may also be called a “layer”. If the “thin film” needs a patterning process in an entire preparation process, it is called a “thin film” before the patterning process, and called a “layer” after the patterning process. The “layer” after the patterning process includes at least one “pattern”. “A and B being arranged on a same layer” mentioned in the present disclosure means that A and B are formed simultaneously through a same patterning process, and a “thickness” of a film layer is a dimension of the film layer in a direction perpendicular to a display substrate. In the exemplary embodiments of the present disclosure, “an orthographic projection of A includes an orthographic projection of B” or “an orthographic projection of B is within a range of an orthographic projection of A” means that a boundary of the orthographic projection of B falls within a range of a boundary of the orthographic projection of A, or the boundary of the orthographic projection of A coincides with the boundary of the orthographic projection of B.

In an exemplary implementation, the preparation process of the detection circuit may include following operations.

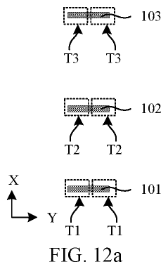

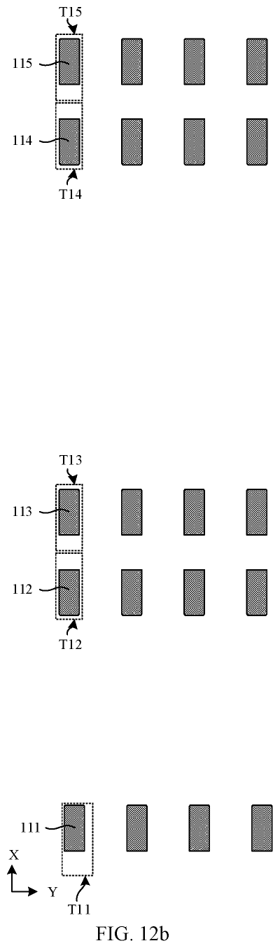

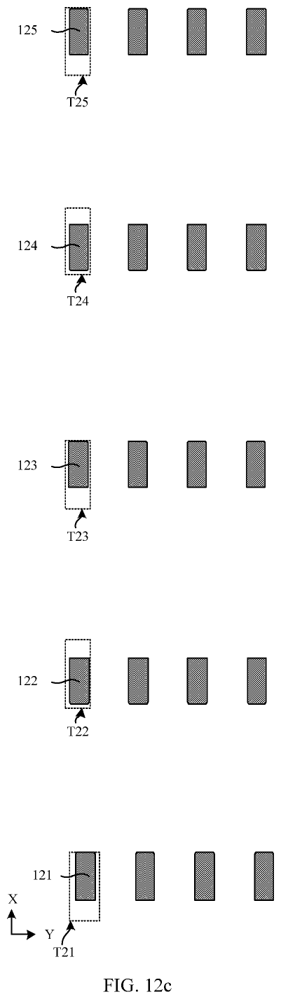

(1) A pattern of a semiconductor layer is formed on a base substrate. In an exemplary implementation, forming the pattern of the semiconductor layer on the base substrate may include: sequentially depositing a first insulation thin film and a semiconductor thin film on the base substrate, patterning the semiconductor thin film by a patterning process to form a first insulation layer covering the entire base substrate, and a pattern of a semiconductor layer arranged on the first insulation layer. The pattern of the semiconductor layer includes at least multiple active layers of a switching unit, multiple active layers of a first detection sub-unit and multiple active layers of a second detection sub-unit, as shown in FIG. 12a, FIG. 12b and FIG. 12c. FIG. 12a shows a structure of region A in FIG. 11, FIG. 12b shows a structure of region B in FIG. 11, illustrating four first detection sub-units, and FIG. 12c shows a structure of region C in FIG. 11, illustrating four second detection sub-units.

As shown in FIG. 12a, in an exemplary implementation, the multiple active layers of the switching unit may include a first active layer 101, a second active layer 102, and a third active layer 103 arranged sequentially along a first direction X, and each active layer may be in a strip shape extending along a second direction Y.

In an exemplary implementation, the first active layer 101 may be used as an active layer of two first transistors T1, the second active layer 102 may be used as an active layer of two second transistors T2, and the third active layer 103 may be used as an active layer of two third transistors T3.

As shown in FIG. 12b, in an exemplary implementation, the multiple first detection sub-units may be sequentially arranged along the second direction Y, wherein multiple active layers of each of the first detection sub-unit may include an eleventh active layer 111, a twelfth active layer 112, a thirteenth active layer 113, a fourteenth active layer 114, and a fifteenth active layer 115 arranged sequentially along the first direction X, and each active layer may be in a strip shape extending along the first direction X.

In an exemplary implementation, the eleventh active layer 111 may be used as an active layer of a eleventh transistor T11, the twelfth active layer 112 may be used as an active layer of a twelfth transistor T12, the thirteenth active layer 113 may be used as an active layer of a thirteenth transistor T13, the fourteenth active layer 114 may be used as an active layer of a fourteenth transistor T14, and the fifteenth active layer 115 may be used as an active layer of a fifteenth transistor T15.

As shown in FIG. 12c, In an exemplary implementation, the multiple second detection sub-units may be sequentially arranged along the second direction Y, wherein multiple active layers of each of the second detection sub-unit may include a twenty-first active layer 121, a twenty-second active layer 122, a twenty-third active layer 123, a twenty-fourth active layer 124, and a twenty-fifth active layer 125 arranged sequentially along the first direction X, and each active layer may be in a strip shape extending along the first direction X.

In an exemplary implementation, the twenty-first active layer 121 may be used as an active layer of a twenty-first transistor T21, the twenty-second active layer 122 may be used as an active layer of a twenty-second transistor T22, the twenty-third active layer 123 may be used as an active layer of a twenty-third transistor T23, the twenty-fourth active layer 124 may be used as an active layer of a twenty-fourth transistor T24, and the twenty-fifth active layer 125 may be used as an active layer of a twenty-fifth transistor T25.

In an exemplary implementation, shapes of multiple active layers in the switching unit may be substantially the same, patterns of semiconductors in the multiple first detection sub-units may be substantially the same, and patterns of semiconductors in the multiple second detection sub-units may be substantially the same.

In an exemplary implementation, the base substrate may be a flexible substrate or a rigid substrate, which is not limited in the present disclosure.

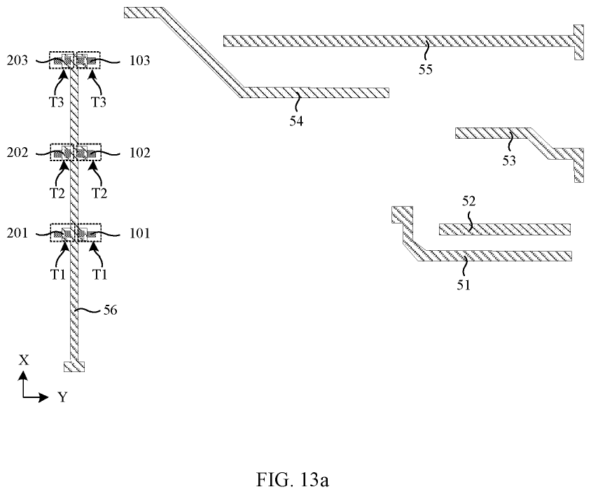

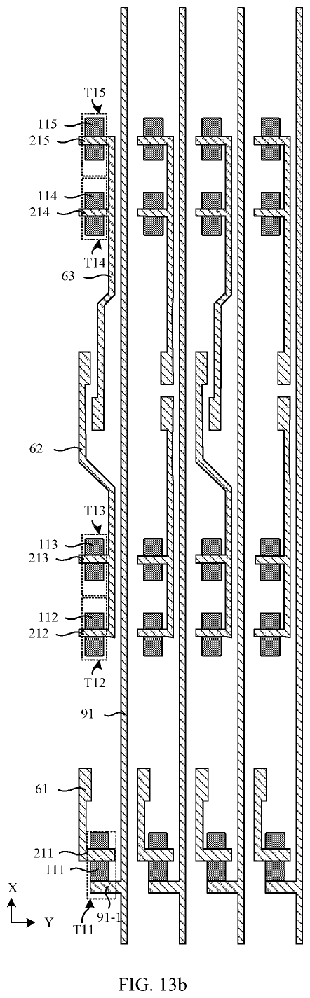

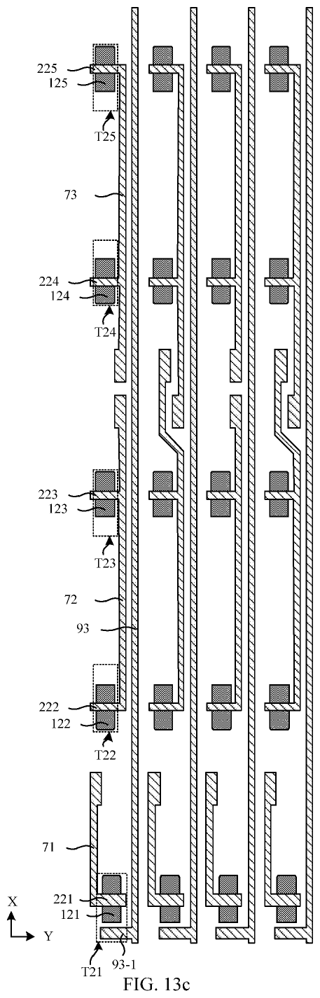

(2) A pattern of a first conductive layer is formed. In an exemplary implementation, forming the pattern of the first conductive layer may include: sequentially depositing a second insulation thin film and a first conductive thin film on the base substrate on which the aforementioned patterns are formed, patterning the first conductive thin film by a patterning process to form a second insulation layer covering the pattern of the semiconductor layer, and a pattern of the first conductive layer arranged on the second insulation layer. The pattern of first conductive layer at least includes: a switching connection line of a switching unit, multiple signal connection lines and multiple gate electrodes, multiple gate connection lines, multiple gate electrodes, and a first transmission line of the first detection sub-units, and multiple gate connection lines, multiple gate electrodes, and a third transmission line of the second detection sub-units, as shown in FIG. 13a, FIG. 13b, and FIG. 13c. FIG. 13a is a structure of the region A in FIG. 11, FIG. 13b is a structure of the region B in FIG. 11, and FIG. 13c is a structure of the region C in FIG. 11. In an exemplary implementation, the first conductive layer may be referred to as a first gate metal (GATE1) layer.

As shown in FIG. 13a, in an exemplary implementation, multiple gate electrodes of the switching unit may include a first gate electrode 201, a second gate electrode 202, and a third gate electrode 203 arranged sequentially along the first direction X. Each gate electrode may have a rectangular ring shape in which an orthographic projection of two sides extending along the first direction X on the base substrate is at least partially overlapped with an orthographic projection of the corresponding active layer on the base substrate to form gate electrodes of the two transistors. An orthographic projection of two sides of the first gate electrode 201 extending along the first direction X on the base substrate is at least partially overlapped with an orthographic projection of the first active layer 101 on the base substrate as gate electrodes of the two first transistors T1. An orthographic projection of two sides of the second gate electrode 202 extending along the first direction X on the base substrate is at least partially overlapped with an orthographic projection of the second active layer 102 on the base substrate as gate electrodes of the two second transistors T2. An orthographic projection of two sides of the third gate electrode 203 extending along the first direction X on the base substrate is at least partially overlapped with an orthographic projection of the third active layer 103 on the base substrate as gate electrodes of the two third transistors T3.

In an exemplary implementation, a switching connection line 56 of the switching unit may be in linear shape extending along the first direction X, and is connected to the first gate electrode 201, the second gate electrode 202, and the third gate electrode 203 respectively, and the switching connection line 56 is configured to be connected to a switching control line to be formed subsequently.

In an exemplary implementation, the first gate electrode 201, the second gate electrode 202, the third gate electrode 203, and the switching connection line 56 may be connected to each other to form an integrated structure.

In an exemplary implementation, multiple signal connection lines of the switching unit may include a first signal connection line 51, a second signal connection line 52, a third signal connection line 53, a fourth signal connection line 54, and a fifth signal connection line 55 arranged sequentially along the first direction X, all of the five signal connection lines are located on a side of the switching connection line 56 in the second direction Y.

In an exemplary implementation, the first signal connection line 51 is configured as a connection line for a second detection line to be formed subsequently, the second signal connection line 52 is configured as a connection line for a first detection line to be formed subsequently, the third signal connection line 53 is configured as a connection line for a third detection line to be formed subsequently, the fourth signal connection line 54 is configured as a connection line for a third control line to be formed subsequently, and the fifth signal connection line 55 is configured as a connection line for a fifth detection line to be formed subsequently. The first signal connection lines 51 to the fifth signal connection lines 55 are used as connection lines of the signal lines to be formed subsequently, thereby avoiding intersection of the signal lines and facilitating arrangement of the signal lines to be formed subsequently.

As shown in FIG. 13b, in an exemplary implementation, multiple gate electrodes of the first detection sub-unit may include an eleventh gate electrode 211, a twelfth gate electrode 212, a thirteenth gate electrode 213, a fourteenth gate electrode 214, and a fifteenth gate electrode 215 arranged sequentially along the first direction X. Each gate electrode may have a strip shape extending along the second direction Y and may be located in a central area of the corresponding active layer in the first direction X, and an orthographic projection of the strip shape on the base substrate is at least partially overlapped with an orthographic projection of the corresponding active layer on the base substrate. The eleventh gate electrode 211 may be used as a gate electrode of the eleventh transistor T11, the twelfth gate electrode 212 may be used as a gate electrode of the twelfth transistor T12, the thirteenth gate electrode 213 may be used as a gate electrode of the thirteenth transistor T13, the fourteenth gate electrode 214 may be used as a gate electrode of the fourteenth transistor T14, and the fifteenth gate electrode 215 may be used as a gate electrode of the fifteenth transistor T15.

In an exemplary implementation, gate connection lines of the first detection sub-unit may include an eleventh gate connection line 61, a twelfth gate connection line 62 and a thirteenth gate connection line 63.

In the exemplary implementation, the eleventh gate connection line 61 may be in a linear shape in which a main body portion extends along the first direction X, an end of the eleventh gate connection line 61 in an direction opposite to the first direction X is connected to the eleventh gate electrode 211, and the eleventh gate connection line 61 is configured to be connected to a first control line to be formed subsequently.

In an exemplary implementation, the twelfth gate connection line 62 may be in a linear shape in which the main body portion extends along the first direction X, an end of the twelfth gate connection line 62 in the direction opposite to the first direction X is connected simultaneously to the twelfth gate electrode 212 and the thirteenth gate electrode 213, and the twelfth gate connection line 62 is configured to be connected to a second control line to be formed subsequently.

In an exemplary implementation, the thirteenth gate connection line 63 may be in a linear shape in which the main body portion extends along the first direction X, an end of the thirteenth gate connection line 63 in the first direction X is connected simultaneously to the fourteenth gate electrode 214 and the fifteenth gate electrode 215, and the thirteenth gate connection line 63 is configured to be connected to the third control line to be formed subsequently.

In an exemplary implementation, a first transmission line 91 of the first detection sub-unit may be in a linear shape in which the main body portion extends along the first direction X and may be located on a side of multiple active layers in the second direction Y, and the first transmission line 91 is configured to be connected to a first data line connected to a G sub-pixel in the display area.

In an exemplary implementation, an eleventh connection block 91-1 is provided on the first transmission line 91, the eleventh connection block 91-1 is located on a side of the eleventh active layer 111 in the direction opposite to the first direction X, and the eleventh connection block 91-1 is configured to be connected to an eleventh active layer 111 through an eleventh connection electrode to be formed subsequently.

In an exemplary implementation, patterns of first conductive layers of the odd-numbered first detection sub-units may be substantially the same along the first direction X, patterns of first conductive layers of the even-numbered first detection sub-units may be substantially the same, but the patterns of the first conductive layers of the odd-numbered first detection sub-units may be different from the patterns of the first conductive layers of the even-numbered first detection sub-units.

In an exemplary implementation, shapes and positions of the eleventh gate electrodes 211 to the fifteenth gate electrodes 215, the eleventh gate connection line 61 and the first transmission line 91 in the multiple first detection sub-units are substantially the same, and the shapes of twelfth gate connection lines 62 and thirteenth gate connection lines 63 in the odd-numbered first detection sub-units are different from those in the even-numbered first detection sub-units.

As shown in FIG. 13c, in an exemplary implementation, multiple gate electrodes of the second detection sub-unit may include an twenty-first gate electrode 221, a twenty-second gate electrode 222, a twenty-third gate electrode 223, a twenty-fourth gate electrode 224, and a twenty-fifth gate electrode 225 arranged sequentially along the first direction X. Each gate electrode may have a strip shape extending along the second direction Y and may be located in a central area of the corresponding active layer in the first direction X, and an orthographic projection of the strip shape on the base substrate is at least partially overlapped with an orthographic projection of the corresponding active layer on the base substrate. The twenty-first gate electrode 221 may be used as a gate electrode of the twenty-first transistor T21, the twenty-second gate electrode 222 may be used as a gate electrode of the twenty-second transistor T22, the twenty-third gate electrode 223 may be used as a gate electrode of the twenty-third transistor T23, the twenty-fourth gate electrode 224 may be used as a gate electrode of the twenty-fourth transistor T24, and the twenty-fifth gate electrode 225 may be used as a gate electrode of the twenty-fifth transistor T25.

In an exemplary implementation, gate connection lines of a second detection sub-unit may include a twenty-first gate connection line 71, a twenty-second gate connection line 72 and a twenty-third gate connection line 73.

In the exemplary implementation, the twenty-first gate connection line 71 may be in a linear shape in which the main body portion extends along the first direction X, an end of the eleventh gate connection line 71 in the direction opposite to the first direction X is connected to the eleventh gate electrode 221, and an twenty-first gate connection line 71 is configured to be connected to the first control line to be formed subsequently.

In an exemplary implementation, the twenty-second gate connection line 72 may be in a linear shape in which the main body portion extends along the first direction X, an end of the twenty-second gate connection line 72 in the direction opposite to the first direction X is connected simultaneously to the twelfth gate electrode 222 and a twenty-third gate electrode 223, and the twenty-second gate connection line 72 is configured to be connected to the second control line to be formed subsequently.

In an exemplary implementation, the twenty-third gate connection line 73 may be in a linear shape in which the main body portion extends along the first direction X, an end of the first direction X of the twenty-third gate connection line 73 is connected simultaneously to the twenty-fourth gate electrode 224 and the twenty-fifth gate electrode 225, and the twenty-third gate connection line 73 is configured to be connected to the third control line to be formed subsequently.

In an exemplary implementation, a third transmission line 93 of the second detection sub-unit may be in a linear shape in which the main body portion extends along the first direction X and may be located on a side of multiple active layers in the second direction Y, and the third transmission line 93 is configured to be connected to a second data line connected to a G sub-pixel in the display area.

In an exemplary implementation, an thirty-first connection block 93-1 is provided on the third transmission line 93, the thirty-first connection block 93-1 is located on a side of the twenty-first active layer 121 in the direction opposite to the first direction X, and the thirty-first connection block 93-1 is configured to be connected to the twenty-first active layer 121 through a twenty-first connection electrode to be formed subsequently.

In an exemplary implementation, patterns of first conductive layers of the odd-numbered second detection sub-units may be substantially the same along the first direction X, patterns of first conductive layers of the even-numbered second detection sub-units may be substantially the same, but the patterns of the first conductive layers of the odd-numbered second detection sub-units may be different from the patterns of the first conductive layers of the even-numbered second detection sub-units.

In an exemplary implementation, shapes and positions of the twenty-first gate electrodes 221 to the twenty-fifth gate electrodes 225, the twenty-first gate connection lines 71 and the third transmission lines 93 in multiple second detection sub-units are substantially the same, and shapes of the twenty-second gate connection lines 72 and the twenty-second gate connection lines 73 in the odd-numbered second detection sub-units are different from those in the even-numbered second detection sub-units.

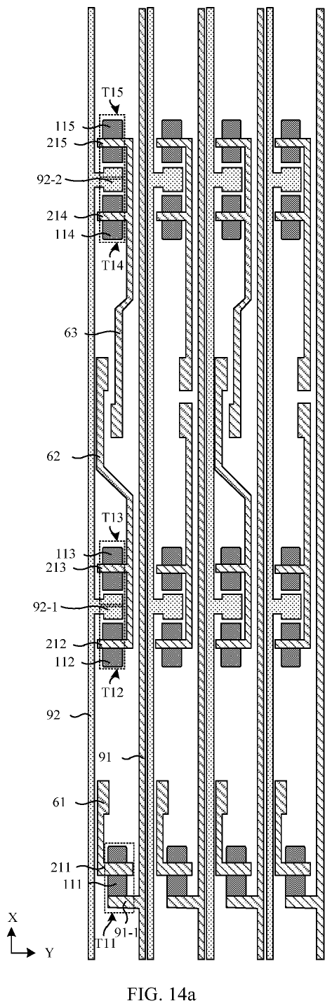

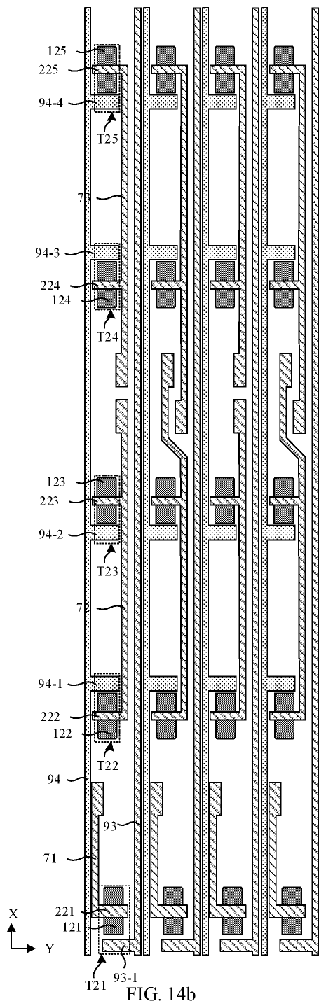

(3) A pattern of a second conductive layer is formed. In an exemplary implementation, forming the pattern of the second conductive layer may include: depositing a third insulation thin film and a second conductive thin film sequentially on the base substrate on which the aforementioned patterns are formed, and patterning the second conductive thin film through a patterning process to form a third insulation layer covering the first conductive layer and a pattern of a second conductive layer arranged on the third insulation layer. The pattern of the second conductive layer at least include a second transmission line of a first detection sub-unit and a fourth transmission line of a second detection sub-unit, as shown in FIG. 14a and FIG. 14b. FIG. 14a is a structure of the region A in FIG. 11, and FIG. 14b is a structure of the region C in FIG. 11 In an exemplary implementation, the second conductive layer may be referred to as a second gate metal (GATE2) layer.

As shown in FIG. 14a, in an exemplary implementation, a second transmission line 92 of the first detection sub-unit may be in a linear shape in which the main body portion extends along the direction opposite to the first direction X and may be located on a side of multiple active layers in the second direction Y, and the second transmission line 92 is configured to be connected to a first data line connected to a B sub-pixel and a R sub-pixel in the display area.

In an exemplary implementation, a twenty-first connection block 92-1 and a twenty-second connection block 92-2 may be provided on the second transmission line 92. The twenty-first connection block 92-1 may be located between a twelfth active layer 112 and a thirteenth active layer 113, and the twenty-first connection block 92-1 is configured to be connected simultaneously to the twelfth active layer 112 and the thirteenth active layer 113 through a twelfth connection electrode to be formed subsequently. The twenty-second connection block 92-2 may be located between a fourteenth active layer 114 and a fifteenth active layer 115, and the twenty-second connection block 92-2 is configured to be connected simultaneously to the fourteenth active layer 114 and the thirteenth active layer 115 through a thirteenth connection electrode to be formed subsequently.

In an exemplary implementation, patterns of the second conductive layers of the multiple first detection sub-units may be substantially the same.

As shown in FIG. 14b, in an exemplary implementation, a fourth transmission line 94 of the second detection sub-unit may be in a linear shape in which the main body portion extends along the direction opposite to the first direction X and may be located on a side of multiple active layers in the second direction Y, and the fourth transmission line 94 is configured to be connected to a second data line connected to a B sub-pixel and a R sub-pixel in the display area.

In an exemplary implementation, a forty-first connection block 94-1, a forty-second connection block 94-2, a forty-third connection block 94-3, and a forty-fourth connection block 94-4 may be provided on the fourth transmission line 94. The forty-first connection block 94-1 may be located on a side of the twenty-second active layer 122 in the first direction X, and the forty-first connection block 94-1 is configured to be connected to the twenty-second active layer 122 through a twenty-second connection electrode to be formed subsequently. The forty-second connection block 94-2 may be located on a side of the twenty-third active layer 123 in the direction opposite to the first direction X, and the forty-second connection block 94-2 is configured to be connected to the twenty-third active layer 123 through a twenty-third connection electrode to be formed subsequently. The forty-third connection block 94-3 may be located on a side of the twenty-fourth active layer 124 in the first direction X, and the forty-third connection block 94-3 is configured to be connected to the twenty-fourth active layer 124 through a twenty-fourth connection electrode to be formed subsequently. The forty-fourth connection block 94-4 may be located on a side of the twenty-fifth active layer 125 in the direction opposite to the first direction X, and the forty-fourth connection block 94-4 is configured to be connected to the twenty-fifth active layer 125 through a twenty-fifth connection electrode to be formed subsequently.

In an exemplary implementation, patterns of the second conductive layers of the multiple second detection sub-units may be substantially the same.

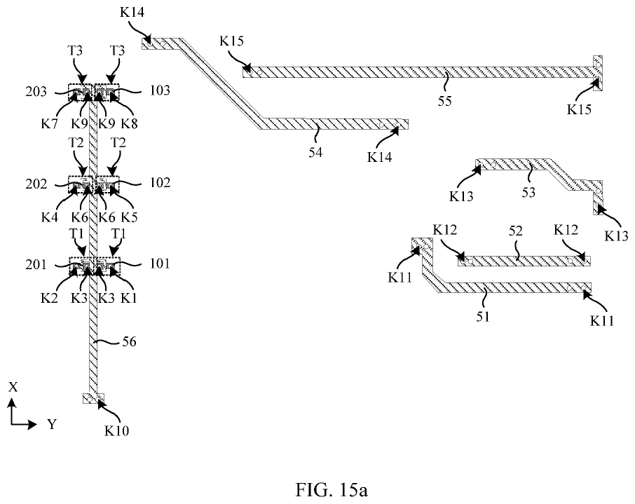

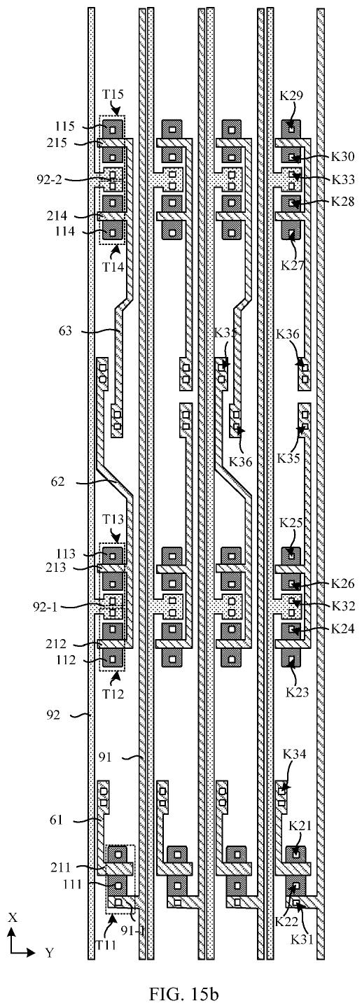

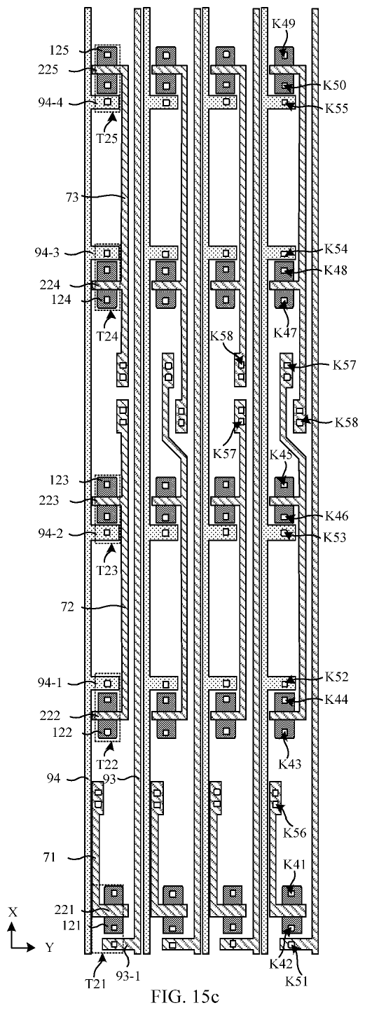

(4) A pattern of a fourth insulation layer is formed. In an exemplary implementation, forming the pattern of the fourth insulation layer may include: depositing a fourth insulation thin film on the base substrate on which the aforementioned patterns are formed, and patterning the fourth insulation thin film through a patterning process to form a fourth insulation layer covering the pattern of the second conductive layer, and multiple vias are formed on the fourth insulation layer, as shown in FIG. 15a, FIG. 15b and FIG. 15c. FIG. 15a is a structure of the region A in FIG. 11, FIG. 15b is a structure of the region B in FIG. 11, and FIG. 15c is a structure of the region C in FIG. 11.

As shown in FIG. 15a, in an exemplary implementation, multiple switching units may include a first via K1, a second via K2, third vias K3, a fourth via K4, a fifth via K5, sixth vias K6, a seventh via K7, an eighth via K8, ninth vias K9, a tenth via K10, eleventh vias K11, twelfth vias K12, thirteenth vias K13, fourteenth vias K14, and fifteenth vias K15.

In an exemplary implementation, an orthographic projection of the first via K1 on the base substrate may be located within a range of an orthographic projection of a first region of the first active layer 101 on the base substrate. The second insulation layer, the third insulation layer, and the fourth insulation layer in the first via K1 are etched away to expose a surface of the first region of the first active layer 101, and the first via K1 is configured such that the first detection line to be formed subsequently is connected to the first region of the first active layer 101 through the via.

In an exemplary implementation, an orthographic projection of the second via K2 on the base substrate may be located within a range of an orthographic projection of a second region of the first active layer 101 on the base substrate. The second insulation layer, the third insulation layer and the fourth insulation layer in the second via K2 are etched away to expose a surface of the second region of the first active layer 101, and the second via K2 is configured such that the second detection line to be formed subsequently is connected to the second region of the first active layer 101 through the via.

In an exemplary implementation, an orthographic projection of at least two third vias K3 on the base substrate may be located within a range of an orthographic projection of a third region of the first active layer 101 on the base substrate, the at least two third vias K3 are located between the first via K1 and the second via K2. The second insulation layer, the third insulation layer, and the fourth insulation layer in the third vias K3 are etched away to expose a surface of the third region of the first active layer 101, and the at least two third vias K3 are configured such that the first detection line to be formed subsequently is connected to the third region of the first active layer 101 through the vias.

In an exemplary implementation, an orthographic projection of the fourth via K4 on the base substrate may be located within a range of an orthographic projection of a first region of the second active layer 102 on the base substrate. The second insulation layer, the third insulation layer, and the fourth insulation layer in the fourth via K4 are etched away to expose a surface of the first region of the second active layer 102, and the first via K4 is configured such that the third detection line to be formed subsequently is connected to the first region of the second active layer 102 through the via.

In an exemplary implementation, an orthographic projection of the fifth via K5 on the base substrate may be located within a range of an orthographic projection of a second region of the second active layer 102 on the base substrate. The second insulation layer, the third insulation layer and the fourth insulation layer in the fifth via K5 are etched away to expose a surface of the second region of the second active layer 102, and the fifth via K5 is configured such that a fourth detection line to be formed subsequently is connected to the second region of the second active layer 102 through the via.

In an exemplary implementation, an orthographic projection of at least two sixth vias K6 on the base substrate may be located within a range of an orthographic projection of a third region of the second active layer 102 on the base substrate, and the at least two two sixth vias K6 are located between the fourth via K4 and the fifth via K5. The second insulation layer, the third insulation layer, and the fourth insulation layer in the sixth vias K6 are etched away to expose a surface of the third region of the second active layer 102, and the at least two sixth vias K6 are configured such that a second connection electrode to be formed subsequently is connected to the third region of the second active layer 102 through the vias.

In an exemplary implementation, an orthographic projection of the seventh via K7 on the base substrate may be located within a range of an orthographic projection of a first region of the third active layer 103 on the base substrate. The second insulation layer, the third insulation layer, and the fourth insulation layer in the seventh via K7 are etched away to expose a surface of the first region of the third active layer 103, and the seventh via K7 is configured such that a fifth detection line to be formed subsequently is connected to the first region of the third active layer 103 through the via.

In an exemplary implementation, an orthographic projection of an eighth via K8 on the base substrate may be located within a range of an orthographic projection of a second region of the third active layer 103 on the base substrate. The second insulation layer, the third insulation layer and the fourth insulation layer in the eighth via K8 are etched away to expose a surface of the second region of the third active layer 103, and the eighth via K8 is configured such that a sixth detection line to be formed subsequently is connected to the second region of the third active layer 103 through the via.

In an exemplary implementation, an orthographic projection of at least two ninth vias K9 on the base substrate may be located within a range of an orthographic projection of a third region of the third active layer 103 on the base substrate, and the at least two two sixth vias K9 are located between the seventh via K7 and the eighth via K8. The second insulation layer, the third insulation layer, and the fourth insulation layer in the ninth vias K9 are etched away to expose a surface of the third region of the third active layer 103, and the at least two sixth vias K9 are configured such that a third connection electrode to be formed subsequently is connected to the third region of the third active layer 103 through the vias.

In an exemplary implementation, an orthographic projection of the tenth via K10 on the base substrate may be located within a range of an orthographic projection of the switching connection line 56 on the base substrate. The third insulation layer and the fourth insulation layer in the tenth via K10 are etched away to expose a surface of the switching connection line 56, and the tenth via K10 is configured such that the switching control line to be formed subsequently is connected to the switching connection line 56 through the via.

In an exemplary implementation, an orthographic projection of at least two eleventh vias K11 on the base substrate may be within a range of an orthographic projection of two ends of the first signal connection line 51 on the base substrate. The third insulation layer and the fourth insulation layer in the eleventh vias K11 are etched away to expose surfaces of the two ends of the first signal connection line 51, and the eleventh vias K11 are configured such that the second detection line to be formed subsequently is connected to the first signal connection line 51 through the vias, and the first signal connection line 51 is used as a bridge line for the second detection line to be formed subsequently.

In an exemplary implementation, an orthographic projection of at least two twelfth vias K12 on the base substrate may be within a range of an orthographic projection of two ends of the second signal connection line 52 on the base substrate. The third insulation layer and the fourth insulation layer in the twelfth vias K12 are etched away to expose surfaces of the two ends of the second signal connection line 52, and the twelfth vias K12 are configured such that the first detection line to be formed subsequently is connected to the second signal connection line 52 through the vias, and the second signal connection line 52 is used as a bridge line for the first detection line to be formed subsequently.

In an exemplary implementation, an orthographic projection of at least two thirteenth vias K13 on the base substrate may be within a range of an orthographic projection of two ends of the third signal connection line 53 on the base substrate. The third insulation layer and the fourth insulation layer in the thirteenth vias K13 are etched away to expose surfaces of the two ends of the third signal connection line 53, and the thirteenth vias K13 are configured such that a third detection line to be formed subsequently is connected to the third signal connection line 53 through the vias, and the third signal connection line 53 is used as a bridge line for the third detection line to be formed subsequently.

In an exemplary implementation, an orthographic projection of at least two fourteenth via K14 on the base substrate may be within a range of an orthographic projection of two ends of a fourth signal connection line 54 on the base substrate. The third insulation layer and the fourth insulation layer in the fourteenth vias K14 are etched away to expose surfaces of the two ends of the fourth signal connection line 54, and the fourteenth vias K14 are configured such that the third control line to be formed subsequently is connected to to the fourth signal connection line 54 through the vias, and the fourth signal connection line 54 is used as a bridge line for the third control line to be formed subsequently.

In an exemplary implementation, an orthographic projection of at least two fifteenth vias K15 on the base substrate may be within a range of an orthographic projection of two ends of the third signal connection line 53 on the base substrate. The third insulation layer and the fourth insulation layer in the fifteenth vias K15 are etched away to expose surfaces of the two ends of the third signal connection line 53, and the fifteenth vias K15 are configured such that the fifth detection line to be formed subsequently to the third signal connection line 53 through the vias, such that the third signal connection line 53 is used as a bridge line for the fifth detection line to be formed subsequently.

In an exemplary implementation, the tenth vias K10 to the fifteenth vias K15 may be provided in multiple to improve connection reliability.

As shown in FIG. 15b, in an exemplary implementation, multiple first detection sub-units may include a twenty-first via K21, a twenty-second via K22, a twenty-third via K23, a twenty-fourth via K24, a twenty-fifth via K25, a twenty-sixth via K26, a twenty-seventh via K27, a twenty-eighth via K28, a twenty-ninth via K29, a thirtieth via K30, a thirty-first via K31, a thirty-second via K32, a thirty-third via K33, a thirty-fourth via K34, a thirty-fifth via K35 and a thirty-sixth via K36.

In an exemplary implementation, an orthographic projection of the twenty-first via K21 on the base substrate may be located within a range of an orthographic projection of a first region of the eleventh active layer 111 on the base substrate. The second insulation layer, the third insulation layer, and the fourth insulation layer in the twenty-first via K21 are etched away to expose a surface of the first region of the eleventh active layer 111, and the twenty-first via K21 is configured such that the first detection line to be formed subsequently is connected to the first region of the eleventh active layer 111 through the via.

In an exemplary implementation, an orthographic projection of the twenty-second via K22 on the base substrate may be located within a range of an orthographic projection of a second region of the eleventh active layer 111 on the base substrate. The second insulation layer, the third insulation layer and the fourth insulation layer in the twenty-second via K22 are etched away to expose a surface of the second region of the eleventh active layer 111, and the twenty-second via K22 is configured such that the eleventh connection electrode to be formed subsequently is connected to the second region of the eleventh active layer 111 through the via.

In an exemplary implementation, an orthographic projection of the twenty-third via K23 on the base substrate may be located within a range of an orthographic projection of a first region of the twelfth active layer 112 on the base substrate. The second insulation layer, the third insulation layer, and the fourth insulation layer in the twenty-third via K23 are etched away to expose a surface of the first region of the twelfth active layer 112, and the twenty-third via K23 is configured such that the third detection line to be formed subsequently is connected to the first region of the twelfth active layer 112 through the via.

In an exemplary implementation, an orthographic projection of the twenty-fourth via K24 on the base substrate may be located within a range of an orthographic projection of a second region of the twelfth active layer 112 on the base substrate. The second insulation layer, the third insulation layer and the fourth insulation layer in the twenty-fourth via K24 are etched away to expose a surface of the second region of the twelfth active layer 112, and the twenty-fourth via K24 is configured such that the twelfth connection electrode to be formed subsequently is connected to the second region of the twelfth active layer 112 through the via.

In an exemplary implementation, an orthographic projection of the twenty-fifth via K25 on the base substrate may be located within a range of an orthographic projection of a first region of the thirteenth active layer 113 on the base substrate. The second insulation layer, the third insulation layer, and the fourth insulation layer in the twenty-fifth via K25 are etched away to expose a surface of the first region of the thirteenth active layer 113, and the twenty-fifth via K25 is configured such that the third detection line to be formed subsequently is connected to the first region of the thirteenth active layer 113 through the via.

In an exemplary implementation, an orthographic projection of the twenty-sixth via K26 on the base substrate may be located within a range of an orthographic projection of a second region of the thirteenth active layer 113 on the base substrate. The second insulation layer, the third insulation layer and the fourth insulation layer in the twenty-sixth via K26 are etched away to expose a surface of the second region of the thirteenth active layer 113, and the twenty-sixth via K26 is configured such that the twelfth connection electrode to be formed subsequently is connected to the second region of the thirteenth active layer 113 through the via.

In an exemplary implementation, an orthographic projection of the twenty-seventh via K27 on the base substrate may be located within a range of an orthographic projection of a first region of the fourteenth active layer 114 on the base substrate. The second insulation layer, a third insulation layer, and a fourth insulation layer in the twenty-seventh via K27 are etched away to expose a surface of the first region of the fourteenth active layer 114, and the twenty-third via K27 is configured such that the fifth detection line to be formed subsequently is connected to the first region of the fourteenth active layer 114 through the via.

In an exemplary implementation, an orthographic projection of the twenty-eighth via K28 on the base substrate may be located within a range of an orthographic projection of a second region of the fourteenth active layer 114 on the base substrate. The second insulation layer, the third insulation layer and the fourth insulation layer in the twenty-eighth via K28 are etched away to expose a surface of the second region of the fourteenth active layer 114, and the twenty-eighth via K28 is configured such that the thirteenth connection electrode to be formed subsequently is connected to the second region of the fourteenth active layer 114 through the via.

In an exemplary implementation, an orthographic projection of the twenty-ninth via K29 on the base substrate may be located within a range of an orthographic projection of a first region of the fifteenth active layer 115 on the base substrate. The second insulation layer, the third insulation layer, and the fourth insulation layer in the twenty-ninth via K29 are etched away to expose a surface of the first region of the fifteenth active layer 115, and the twenty-ninth via K29 is configured such that the fifth detection line to be formed subsequently is connected to the first region of the fifteenth active layer 115 through the via.

In an exemplary implementation, an orthographic projection of the thirtieth via K30 on the base substrate may be located within a range of an orthographic projection of a second region of the fifteenth active layer 115 on the base substrate. The second insulation layer, the third insulation layer and the fourth insulation layer in the thirtieth via K30 are etched away to expose a surface of the second region of the fifteenth active layer 115, and the thirtieth via K30 is configured such that the thirteenth connection electrode to be formed subsequently is connected to the second region of the fifteenth active layer 115 through the via.

In an exemplary implementation, an orthographic projection of the thirty-first via K31 on the base substrate may be located within a range of an orthographic projection of the eleventh connection block 91-1 of the first transmission line 91 on the base substrate. The third insulation layer and the fourth insulation layer in the thirty-first via K31 are etched away to expose a surface of the eleventh connection block 91-1, and the thirty-first via K31 is configured such that the eleventh connection electrode to be formed subsequently is connected to the eleventh connection block 91-1 through the via.

In an exemplary implementation, an orthographic projection of the thirty-second via K32 on the base substrate may be located within a range of an orthographic projection of the twenty-first connection block 92-1 of the second transmission line 92 on the base substrate. The fourth insulation layer in the thirty-second via K32 is etched away to expose a surface of the twenty-first connection block 92-1, and the thirty-second via K32 is configured such that the twelfth connection electrode to be formed subsequently is connected to the twenty-first connection block 92-1 through the via.

In an exemplary implementation, an orthographic projection of the thirty-third via K33 on the base substrate may be located within a range of an orthographic projection of the twenty-second connection block 92-2 of the second transmission line 92 on the base substrate. The fourth insulation layer in the thirty-third via K33 are etched away to expose a surface of the twenty-second connection block 92-2, and the thirty-third via K33 is configured such that the thirteenth connection electrode to be formed subsequently is connected to the twenty-second connection block 92-2 through the via.

In an exemplary implementation, an orthographic projection of the thirty-fourth via K34 on the base substrate may be located within a range of an orthographic projection of the eleventh gate connection line 61 on the base substrate. The third insulation layer and the fourth insulation layer in the thirty-fourth via K34 are etched away to expose a surface of the eleventh gate connection line 61, and the thirty-fourth via K34 is configured such that the first control line to be formed subsequently is connected to the eleventh gate connection line 61 through the via.

In an exemplary implementation, an orthographic projection of the thirty-fifth via K35 on the base substrate may be within a range of an orthographic projection of the twelfth gate connection line 62 on the base substrate. The third insulation layer and the fourth insulation layer in the thirty-fifth via K35 are etched away to expose a surface of the twelfth gate connection line 62, a thirty-fifth via K35 in an odd-numbered first detection sub-unit is configured such that the third control line to be formed subsequently is connected to the twelfth gate connection line 62 through the via, and a thirty-fifth via K35 in an even-numbered first detection sub-unit is configured such that connect the second control line to be formed subsequently is connected to to the twelfth gate connection line 62 through the via.

In an exemplary implementation, an orthographic projection of the thirty-sixth via K36 on the base substrate may be within a range of an orthographic projection of the thirteenth gate connection line 63 on the base substrate. The third insulation layer and the fourth insulation layer in the thirty-sixth via K36 are etched away to expose a surface of the thirteenth gate connection line 63, a thirty-sixth via K36 in an odd-numbered first detection sub-unit is configured such that the second control line to be formed subsequently is connected to the thirteenth gate connection line 63 through the via, and a thirty-sixth via K36 in an even-numbered first detection sub-unit is configured such that the third control line to be formed subsequently is connected to the thirteenth gate connection line 63 through the via.

As shown in FIG. 15c, in an exemplary implementation, multiple second detection sub-units may include a forty-first via K41, a forty-second via K42, a forty-third via K43, a forty-fourth via K44, a forty-fifth via K45, a forty-sixth via K46, a forty-seventh via K47, a forty-eighth via K48, a forty-ninth via K49, a fiftieth via K50, a fifty-first via K51, a fifty-second via K52, a fifty-third via K53, a fifty-fourth via K54, a fifty-fifth via K55, a fifty-sixth via K56, a fifty-seventh via K57 and a fifty-eighth via K58.

In an exemplary implementation, an orthographic projection of the forty-first via K41 on the base substrate may be located within a range of an orthographic projection of a first region of the twenty-first active layer 121 on the base substrate. The second insulation layer, the third insulation layer, and the fourth insulation layer in the forty-first via K41 are etched away to expose a surface of the first region of the twenty-first active layer 121, and the forty-first via K41 is configured such that the second detection line to be formed subsequently is connected to the first region of the twenty-first active layer 121 through the via.

In an exemplary implementation, an orthographic projection of the forty-second via K42 on the base substrate may be located within a range of an orthographic projection of a second region of the twenty-first active layer 121 on the base substrate. The second insulation layer, the third insulation layer and the fourth insulation layer in the forty-second via K42 are etched away to expose a surface of the second region of the twenty-first active layer 121, and the forty-second via K42 is configured such that the twenty-first connection electrode to be formed subsequently is connected to the second region of the twenty-first active layer 121 through the via.

In an exemplary implementation, an orthographic projection of the forty-third via K43 on the base substrate may be located within a range of an orthographic projection of a first region of the twenty-second active layer 122 on the base substrate. The second insulation layer, the third insulation layer, and the fourth insulation layer in the forty-third via K43 are etched away to expose a surface of the first region of the twenty-second active layer 122, and the forty-third via K43 is configured such that the fourth detection line to be formed subsequently is connected to the first region of the twenty-second active layer 122 through the via.

In an exemplary implementation, an orthographic projection of the forty-fourth via K44 on the base substrate may be located within a range of an orthographic projection of a second region of the twenty-second active layer 122 on the base substrate. The second insulation layer, the third insulation layer and the fourth insulation layer in the forty-fourth via K44 are etched away to expose a surface of the second region of the twenty-second active layer 122, and the forty-fourth via K44 is configured such that the twenty-second connection electrode to be formed subsequently is connected to the second region of the twenty-second active layer 122 through the via.

In an exemplary implementation, an orthographic projection of the forty-fifth via K45 on the base substrate may be located within a range of an orthographic projection of a first region of the twenty-third active layer 123 on the base substrate. The second insulation layer, the third insulation layer, and the fourth insulation layer in the forty-fifth via K45 are etched away to expose a surface of the first region of the twenty-third active layer 123, and the forty-fifth via K45 is configured such that the fourth detection line to be formed subsequently is connected to the first region of the twenty-third active layer 123 through the via.

In an exemplary implementation, an orthographic projection of the forty-sixth via K46 on the base substrate may be located within a range of an orthographic projection of a second region of the twenty-third active layer 123 on the base substrate. The second insulation layer, the third insulation layer and the fourth insulation layer in the forty-sixth via K46 are etched away to expose a surface of the second region of the twenty-third active layer 123, and the forty-sixth via K46 is configured such that the twenty-third connection electrode to be formed subsequently is connected to the second region of the twenty-third active layer 123 through the via.

In an exemplary implementation, an orthographic projection of the forty-seventh via K47 on the base substrate may be located within a range of an orthographic projection of a first region of the twenty-fourth active layer 124 on the base substrate. The second insulation layer, the third insulation layer, and the fourth insulation layer in the forty-seventh via K47 are etched away to expose a surface of the first region of the twenty-fourth active layer 124, and the forty-second via K47 is configured such that the sixth detection line to be formed subsequently is connected to the first region of the twenty-fourth active layer 124 through the via.

In an exemplary implementation, an orthographic projection of the forty-eighth via K48 on the base substrate may be located within a range of an orthographic projection of a second region of the twenty-fourth active layer 124 on the base substrate. The second insulation layer, the third insulation layer and the fourth insulation layer in the forty-eighth via K48 are etched away to expose a surface of the second region of the twenty-fourth active layer 124, and the forty-eighth via K48 is configured such that the twenty-fourth connection electrode to be formed subsequently is connected to the second region of the twenty-fourth active layer 124 through the via.

In an exemplary implementation, an orthographic projection of the forty-ninth via K49 on the base substrate is located within a range of an orthographic projection of a first region of the twenty-fifth active layer 125 on the base substrate. The second insulation layer, the third insulation layer, and the fourth insulation layer in the forty-ninth via K49 are etched away to expose a surface of the first region of the twenty-fifth active layer 125, and the forty-ninth via K49 is configured such that the sixth detection line to be formed subsequently is connected to the first region of the twenty-fifth active layer 125 through the via.

In an exemplary implementation, an orthographic projection of the fiftieth via K50 on the base substrate may be located within a range of an orthographic projection of the second region of the twenty-fifth active layer 125 on the base substrate. The second insulation layer, the third insulation layer and the fourth insulation layer in the fiftieth via K50 are etched away to expose a surface of the second region of the twenty-fifth active layer 125, and the fiftieth via K50 is configured such that the twenty-fifth connection electrode to be formed subsequently is connected to the second region of the twenty-fifth active layer 125 through the via.

In an exemplary implementation, an orthographic projection of the fifty-first via K51 on the base substrate may be located within a range of an orthographic projection of the thirty-first connection block 93-1 of the third transmission line 93 on the base substrate. The third insulation layer and the fourth insulation layer in the fifty-first via K51 are etched away to expose a surface of the thirty-first connection block 93-1, and the fifty-first via K51 is configured such that the twenty-first connection electrode to be formed subsequently is connected to the thirty-first connection block 93-1 through the via.

In an exemplary implementation, an orthographic projection of the fifty-second via K52 on the base substrate may be located within a range of an orthographic projection of the forty-first connection block 94-1 of the fourth transmission line 94 on the base substrate. The fourth insulation layer in the fifty-second via K52 is etched away to expose a surface of the forty-first connection block 94-1, and the fifty-second via K52 is configured such that the twenty-second connection electrode to be formed subsequently is connected to the forty-first connection block 94-1 through the via.

In an exemplary implementation, an orthographic projection of the fifty-third via K53 on the base substrate may be located within a range of an orthographic projection of the forty-second connection block 94-2 of the fourth transmission line 94 on the base substrate. The fourth insulation layer in the fifty-third via K53 is etched away to expose a surface of the forty-second connection block 94-2, and the fifty-third via K53 is configured such that the twenty-third connection electrode to be formed subsequently is connected to the forty-second connection block 94-2 through the via.

In an exemplary implementation, an orthographic projection of the fifty-fourth via K54 on the base substrate may be located within a range of an orthographic projection of the forty-third connection block 94-3 of the fourth transmission line 94 on the base substrate. The fourth insulation layer in the fifty-fourth via K54 is etched away to expose a surface of the forty-third connection block 94-3, and the fifty-fourth via K54 is configured such that the twenty-fourth connection electrode to be formed subsequently is connected to the forty-third connection block 94-3 through the via.

In an exemplary implementation, an orthographic projection of the fifty-fifth via K55 on the base substrate may be located within a range of an orthographic projection of the forty-fourth connection block 94-4 of the forty transmission line 94 on the base substrate. The fourth insulation layer in the fifty-fifth via K55 is etched away to expose a surface of the forty-fourth connection block 94-4, and the fifty-fifth via K55 is configured such that the twenty-fifth connection electrode to be formed subsequently is connected to the forty-fourth connection block 94-4 through the via.

In an exemplary implementation, an orthographic projection of the fifty-sixth via K56 on the base substrate may be located within a range of an orthographic projection of a thirty-first gate connection line 71 on the base substrate. The third insulation layer and the fourth insulation layer in the fifty-sixth via K56 are etched away to expose a surface of the thirty-first gate connection line 71, and the fifty-sixth via K56 is configured such that the first control line to be formed subsequently is connected to the thirty-first gate connection line 71 through the via.

In an exemplary implementation, an orthographic projection of the fifty-seventh via K57 on the base substrate may be within a range of an orthographic projection of a thirty-second gate connection line 72 on the base substrate. The third insulation layer and the fourth insulation layer in the fifty-seventh via K57 are etched away to expose a surface of the thirty-second gate connection line 72, a fifty-seventh via K57 in an odd-numbered second detection sub-unit is configured such that the second control line to be formed subsequently is connected to the thirty-second gate connection line 72 through the via, and a fifty-seventh via K57 in an even-numbered second detection sub-unit is configured such that the third control line to be formed subsequently is connected to the thirty-second gate connection line 72 through the via.

In an exemplary implementation, an orthographic projection of the fifty-eighth via K58 on the base substrate may be within a range of an orthographic projection of a thirty-third gate connection line 73 on the base substrate. The third insulation layer and the fourth insulation layer in the fifty-eighth via K58 are etched away to expose a surface of the thirty-third gate connection line 73, a fifty-eighth via K58 in an odd-numbered second detection sub-unit is configured such that the third control line to be formed subsequently is connected to the thirty-third gate connection line 73 through the via, and a fifty-eighth via K58 in an even-numbered second detection sub-unit is configured such that the second control line to be formed subsequently is connected to the thirty-third gate connection line 73 through the via.

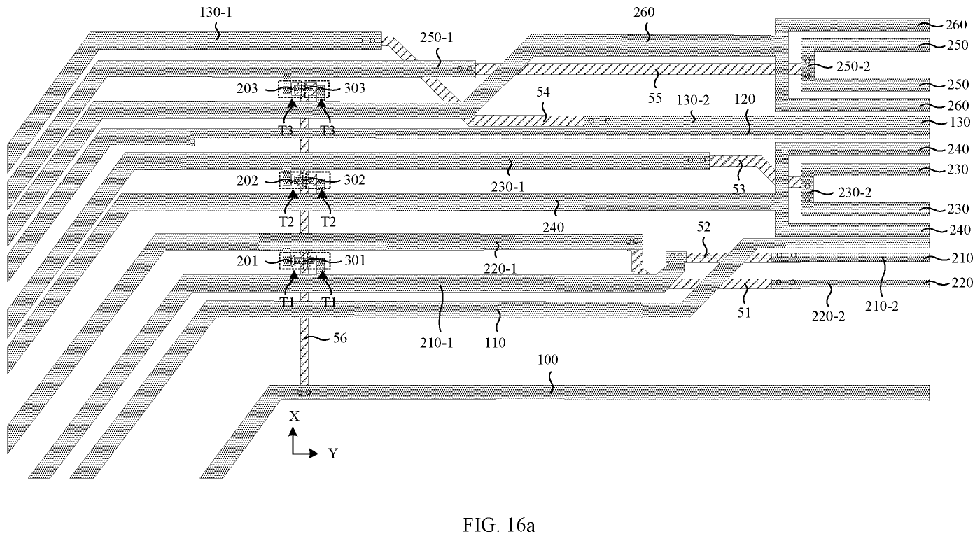

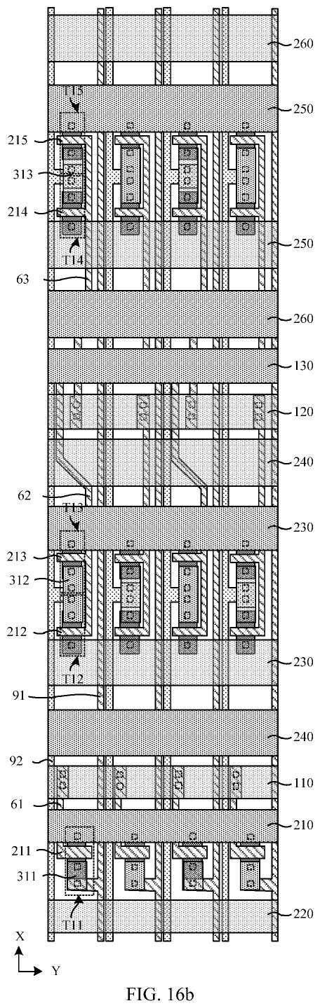

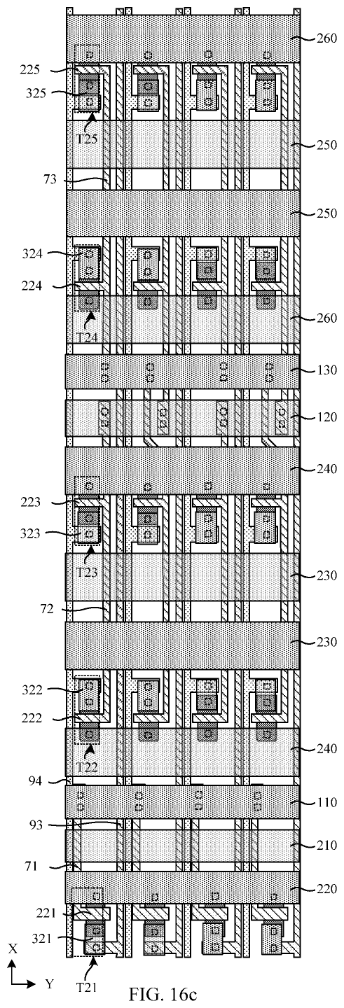

(5) A pattern of a third conductive layer is formed. In an exemplary implementation, forming the pattern of the third conductive layer may include: depositing a third conductive thin film on a base substrate on which the aforementioned pattern is formed, patterning the third conductive thin film by a patterning process, and forming a pattern of a third conductive layer on a fourth insulation layer, as shown in FIG. 16a, FIG. 16b, and FIG. 16c. FIG. 16a shows a structure of the region A in FIG. 11, FIG. 16b shows a structure of the region B in FIG. 11, and FIG. 16c shows a structure of the region C in FIG. 11. In an exemplary implementation, the third conductive layer may be referred to as a first source drain metal layer (SD1).

As shown in FIG. 16a, FIG. 16b and FIG. 16c, the pattern of the third conductive layer may include a switching control line 100, a first control line 110, a second control line 120, a third control line 130, a first detection line 210, a second detection line 220, a third detection line 230, a fourth detection line 240, a fifth detection line 250, a sixth detection line 260, a first connection electrode 301, a second connection electrode 302, a third connection electrode 303, a eleventh connection electrode 311, a twelfth connection electrode 312, a thirteenth connection electrode 313, a twenty-first connection electrode 321, a twenty-second connection electrode 322, a twenty-third connection electrode 323, a twenty-fourth connection electrode 324 and a twenty-fifth connection electrode 325.

In an exemplary implementation, a first end of the switching control line 100 is connected to a switching control pin in the bonding pin region, and a second end of the switching control line 100 extends to the detection circuit region and is connected to a switching connection line 56 through a tenth via K10. Since the switching connection line 56 is connected to a first gate electrode 201, a second gate electrode 202, and a third gate electrode 203, a switching control signal transmitted by the switching control line 100 can be transmitted to the first gate electrode 201, the second gate electrode 202, and the third gate electrode 203 through the switching connection line 56 to control the first transistor T1, the second transistor T2, and the third transistor T3 to be turned on or turned off.

In an exemplary implementation, a first end of the first control line 110 is connected to a first control pin in the bonding pin region, a second end of the first control line 110 extends to the detection circuit region, the first control line 110 is connected to an eleventh gate connection line 61 in each of the first detection sub-units on the one hand through the thirty-fourth via K34, and is also connected to a thirty-first gate connection line 71 in each of the second detection sub-units through the fifty-sixth via hole K56. Since the eleventh gate connection line 61 is connected to an eleventh gate electrode 211, the thirty-first gate connection line 71 is connected to a twenty-first gate electrode 221, so that the first control signal transmitted by the first control line 110 can be transmitted to the eleventh gate electrode 211 and the twenty-first gate electrode 221 through the eleventh gate connection line 61 and the thirty-first gate connection line 71 respectively, so as to control the eleventh transistor T11 and the twenty-first transistor T21 to be turned on and turned off.

In an exemplary implementation, a first end of the second control line 120 is connected to a second control pin in the bonding pin region and a second end of the second control line 120 extends to the detection circuit region. In a first detection unit, the second control line 120 is connected to the thirteenth gate connection line 63 through a thirty-sixth via K36 in an odd-numbered first detection sub-unit on the one hand, and is connected to the twelfth gate connection line 62 through a thirty-fifth via K35 in an even-numbered first detection sub-unit on the other hand. In a second detection unit, the second control line 120 is connected to the thirty-second gate connection line 72 through a fifty-seventh via hole K57 in an odd-numbered second detection sub-unit on the one hand, and is connected to the thirty-third gate connection line 73 through a fifty-eighth via K58 in an even-numbered second detection sub-unit on the other hand.

Since the twelfth gate connection line 62 is connected to the twelfth gate electrode 212 and the thirteenth gate electrode 213, a second control signal transmitted by the second control line 120 can control a twelfth transistor T12 and a thirteenth transistor T13 in the even-numbered first detection sub-unit to be turned on and turned off. Since the twelfth gate connection line 63 is connected to the twelfth gate electrode 214 and the thirteenth gate electrode 215, the second control signal transmitted by the second control line 120 can control a twelfth transistor T14 and a thirteenth transistor T15 in the even-numbered first detection sub-unit to turn on and turn off.

Since the thirty-second gate connection line 72 is connected to the twenty-second gate electrode 222 and the twenty-third gate electrode 223, the second control signal transmitted by the second control line 120 can control the twelfth transistor T22 and the thirteenth transistor T23 in the even-numbered first detection sub-unit to be turned on and turned off. Since the thirty-third gate connection line 73 is connected to the twenty-fourth gate electrode 224 and the twenty-fifth gate electrode 225, the second control signal transmitted by the second control line 120 can control the twelfth transistor T24 and the thirteenth transistor T25 in the even-numbered first detection sub-unit to be turned on and turned off.

In an exemplary implementation, the third control line 130 may include a third control lead-out line 130-1 and a third control extension line 130-2. A first end of the third control lead-out 130-1 is connected to a third control pin in the bonding pin region, and a second end of the third control lead-out 130-1 is connected to a first end of the fourth signal connection line 54 through the fourteenth via K14 after the second end extends to the detection circuit region. A first end of the third control extension line 130-2 is connected to a second end of the fourth signal connection line 54 through the fourteenth via K14, and a second end of the third control extension line 130-2 extends along the second direction Y, such that the third control lead-out line 130-1 and the third control extension line 130-2 form the third control line 130 through the fourth signal connection line 54.

In the first detection unit, the third control line 130 is connected to the twelfth gate connection line 62 through a thirty-fifth via K35 in an odd-numbered first detection sub-unit on the one hand, and is connected to the thirteenth gate connection line 63 through a thirty-sixth via K36 in an even-numbered first detection sub-unit on the other hand. In the second detection unit, the third control line 130 is connected to the thirty-third gate connection line 73 through a fifty-eighth via K58 in an odd-numbered second detection sub-unit on the one hand, and is connected to the thirty-second gate connection line 72 through a fifty-seventh via K57 in an even-numbered second detection sub-unit on the other hand.

Since the twelfth gate connection line 62 is connected to the twelfth gate electrode 212 and the thirteenth gate electrode 213, a third control signal transmitted by the third control line 130 can control a twelfth transistor T12 and a thirteenth transistor T13 in the odd-numbered first detection sub-unit to be turned on and turned off. Since the twelfth gate connection line 63 is connected to the twelfth gate electrode 214 and the thirteenth gate electrode 215, the third control signal transmitted by the third control line 130 can control a twelfth transistor T14 and a thirteenth transistor T15 in the even-numbered first detection sub-unit to be turned on and turned off.

Since the thirty-second gate connection line 72 is connected to the twenty-second gate electrode 222 and the twenty-third gate electrode 223, the third control signal transmitted by the third control line 130 can control a twelfth transistor T22 and a thirteenth transistor T23 in the even-numbered first detection sub-unit to be turned on and turned off. Since the thirty-third gate connection line 73 is connected to the twenty-fourth gate electrode 224 and the twenty-fifth gate electrode 225, the third control signal transmitted by the third control line 130 can control a twelfth transistor T24 and a thirteenth transistor T25 in the odd-numbered first detection sub-unit to be turned on and turned off.

In an exemplary implementation, the first detection line 210 may include a first detection lead-out line 210-1 and a first detection extension line 210-2. A first end of the first detection lead-out 210-1 is connected to a first detection pin in the bonding pin region, and a second end of the first detection lead-out 210-1 is connected to a first end of the second signal connection line 52 through the twelfth via K12 after the second end extends to the detection circuit region. A first end of the first detection extension line 210-2 is connected to a second end of the second signal connection line 52 through the twelfth via K12, and a second end of the first detection extension line 210-2 extends along the second direction Y, such that the first detection lead-out line 210-1 and the first detection extension line 210-2 form the first detection line 210 through the second signal connection line 52.

In an exemplary implementation, the first detection line 210 is connected to the first region of the first active layer 101 through the first via K1 on the one hand, and is connected to a first region of the eleventh active layer 111 in the first detection sub-unit through the twenty-first via K21 on the other hand.

In an exemplary implementation, the second detection line 220 may include a second detection lead-out line 220-1 and a second detection extension line 220-2. A first end of the second detection lead-out 220-1 is connected to a second detection pin in the bonding pin region, and a second end of the second detection lead-out 220-1 is connected to a first end of the first signal connection line 51 through the eleventh via K11 after the second end extends to the detection circuit region. A first end of the second detection extension line 220-2 is connected to a second end of the first signal connection line 51 through the twelfth via K11, and a second end of the second detection extension line 220-2 extends along the second direction Y, such that the second detection lead-out line 220-1 and the second detection extension line 220-2 form the second detection line 220 through the first signal connection line 51.

In an exemplary implementation, the second detection line 220 is connected to the second region of the first active layer 101 through the second via K2 on the one hand, and is connected to a first region of the twenty-first active layer 121 in the second detection sub-unit through the forty-first via K41 on the other hand.

In an exemplary implementation, the third detection line 230 may include a third detection lead-out line 230-1 and a third detection extension line 230-2. A first end of the third detection lead-out 230-1 is connected to a third detection pin in the bonding pin region, and a second end of the third detection lead-out 230-1 is connected to a first end of the third signal connection line 53 through an thirteenth via K13 after the second end extends to the detection circuit region. A first end of the third detection extension line 230-2 is connected to a second end of the first signal connection line 53 through the thirteenth via K13, and a second end of the third detection extension line 230-2 extends along the second direction Y, such that the third detection lead-out line 230-1 and the third detection extension line 230-2 form the third detection line 230 through the third signal connection line 53.

In an exemplary implementation, the third detection line 230 is connected to the first region of the second active layer 102 through the fourth via K4 on the one hand, and the third detection line is expanded into two third detection lines 230 on the other hand, wherein one third detection line 230 is connected to a first region of the twelfth active layer 112 in the first detection sub-unit through the twenty-third via K23, and the other third detection line 230 is connected to a first region of the thirteenth active layer 113 in the first detection sub-unit through the twenty-fifth via K25.

In an exemplary implementation, a first end of the fourth detection line 240 is connected to a fourth detection pin in the bonding pin region, and after a second end of the fourth detection line 240 extends to the detection circuit region, it is connected to the second region of the second active layer 102 through the fifth via K5 on the one hand, and it is expanded into two fourth detection lines 240 on the other hand, wherein one fourth detection line 240 is connected to the first region of the twenty-second active layer 122 through the forty-third via K43, and the other fourth detection line 240 is connected to the first region of the twenty-third active layer 123 through the forty-fifth via K45.

In an exemplary implementation, the fifth detection line 250 may include a fifth detection lead-out line 250-1 and a fifth detection extension line 250-2. A first end of the fifth detection lead-out 250-1 is connected to a fifth detection pin in the bonding pin region, and a second end of the fifth detection lead-out 250-1 is connected to a first end of the fifth signal connection line 55 through the fifteenth via K15 after the second end extends to the detection circuit region. A first end of the fifth detection extension line 250-2 is connected to a second end of a fifth signal connection line 55 through the fifteenth via K15, and a second end of the fifth detection extension line 250-2 extends along the second direction Y, such that the fifth detection lead-out line 250-1 and the fifth detection extension line 250-2 form the fifth detection line 250 through the fifth signal connection line 55.

In an exemplary implementation, the fifth detection line 250 is connected to the first region of the third active layer 103 through the seventh via K7 on the one hand, and is expanded into two fifth detection lines 250 on the other hand, wherein one fifth detection line 250 is connected to the first region of the fourteenth active layer 114 through the twenty-seventh via K27, and the other fifth detection line 250 is connected to the first region of the fifteenth active layer 115 through the twenty-ninth via K29.

In an exemplary implementation, a first end of the sixth detection line 260 is connected to a sixth detection pin of the bonding pin region, and after a second end of the sixth detection line 260 extends to the detection circuit region, it is connected to the second region of the third active layer 103 through the eighth via K8 on the one hand, and it is expanded into two sixth detection lines 260 on the other hand, wherein one sixth detection line 260 is connected to the first region of the twenty-fourth active layer 124 through the forty-seventh via K47, and the other sixth detection line 260 is connected to the first region of the twenty-fifth active layer 125 through the forty-ninth via K49.

In an exemplary implementation, the first connection electrode 301 is arranged between the first detection line 210 and the second detection line 220, and is connected to the third region of the first active layer 101 through two third vias K3. The first connection electrode 301 may be used as a connection electrode for the two first transistors T1, which are both as a first electrode of one first transistor T1 and as a second electrode of the other first transistor T1 to achieve a series-connected structure of the two first transistors T1.

In an exemplary implementation, the second connection electrode 302 is arranged between the third detection line 230 and the fourth detection line 240, and is connected to the third region of the first active layer 102 through two third vias K6. The second connection electrode 302 may be used as a connection electrode for the two second transistors T2, which are both as a first electrode of one second transistor T2 and as a second electrode of the other second transistor T2 to achieve a series-connected structure of the two second transistors T2.

In an exemplary implementation, the third connection electrode 303 is arranged between a fifth detection line 250 and a sixth detection line 260, and is connected to the third region of the third active layer 103 through two ninth vias K9. The third connection electrode 303 may be used as a connection electrode for two third transistors T3, which are both as a first electrode of one third transistor T3 and as a second electrode of the other third transistor T3 to achieve a series-connected structure of two third transistors T3.

In an exemplary implementation, the eleventh connection electrode 311 may be arranged on a side of the eleventh gate electrode 211 in the first detection sub-unit in a direction opposite to the first direction X. The eleventh connection electrode 311 is connected to the second region of the eleventh active layer 111 through the twenty-second via K22 on one hand, and is connected to the eleventh connection block 91-1 of the first transmission line 91 through the thirty-first via K31 on the other hand, so that the eleventh transistor T11 controls on and off between the first detection line 210 and the first transmission line 91. When the eleventh transistor T11 is turned on, a first signal transmitted by the first detection line 210 is transmitted to the first transmission line 91, and the first transmission line 91 transmits the first signal to a first data line connected to a G sub-pixels in the display area.

In an exemplary implementation, the twelfth connection electrode 312 may be arranged between the twelfth gate electrode 212 and the thirteenth gate electrode 213 in the first detection sub-unit. The twelfth connection electrode 312 is connected to the second region of the twelfth active layer 112 through the twenty-fourth via K24 on the other hand, the twelfth connection electrode 312 is connected to the second region of the thirteenth active layer 113 through the twenty-sixth via K26 on the other hand, the twelfth connection electrode 312 is connected to the twenty-first connection block 92-1 of the second transmission line 92 through the thirty-second via K32 on another hand, so that the twelfth transistor T12 and the thirteenth transistor T13 control on and off between the third detection line 230 and the second transmission line 92. When the twelfth transistor T12 and the thirteenth transistor T13 are turned on, a third signal transmitted by the third detection line 230 is transmitted to the second transmission line 92, and the second transmission line 92 transmits the third signal to a first data line connected to a B sub-pixel and a R sub-pixel in the display area.

In an exemplary implementation, the thirteenth connection electrode 313 may be arranged between the fourteenth gate electrode 214 and the fifteenth gate electrode 215 in the first detection sub-unit. The thirteenth connection electrode 313 is connected to the second region of the fourteenth active layer 114 through the twenty-eighth via K28 on one hand, the thirteenth connection electrode 313 is connected to the second region of the fifteenth active layer 115 through the thirtieth via K30 on the other hand, and the thirteenth connection electrode 313 is connected to the twenty-second connection block 92-2 of the second transmission line 92 through the thirty-third via K33 on another hand, so that the fourteenth transistor T14 and the fifteenth transistor T15 control on and off between the fifth detection line 250 and the second transmission line 92. When the fourteenth transistor T14 and the fifteenth transistor T15 are turned on, a fifth signal transmitted by the fifth detection line 250 is transmitted to the second transmission line 92, and the second transmission line 92 transmits the fifth signal to a first data line connected to a B sub-pixel and a R sub-pixel in the display area.

In an exemplary implementation, the twenty-first connection electrode 321 may be arranged on a side of the twenty-first gate electrode 221 in the second detection sub-unit in the direction opposite to the first direction X. The twenty-first connection electrode 321 is connected to the second region of the twenty-first active layer 121 through the forty-second via K42 on one hand, and the twenty-first connection electrode 321 is connected to the thirty-first connection block 93-1 of the third transmission line 93 through the fifty-first via K51 on the other hand, so that the twenty-first transistor T21 controls on and off between the second detection line 220 and the third transmission line 93. When the twenty-first transistor T21 is turned on, a second signal transmitted by the second detection line 220 is transmitted to the third transmission line 93, and the third transmission line 93 transmits the second signal to a second data line connected to a G sub-pixel in the display area.

In an exemplary implementation, the twenty-second connection electrode 322 may be arranged on a side of the twenty-second gate electrode 222 in the second detection sub-unit in the first direction X. The twenty-second connection electrode 322 is connected to the second region of the twenty-second active layer 122 through the forty-fourth via K44 on one hand, and the twenty-second connection electrode 322 is connected to the forty-first connection block 94-1 of the fourth transmission line 94 through the fifty-second via K52 on the other hand, so that the twenty-second transistor T22 controls on and off between the fourth detection line 240 and the fourth transmission line 94. When the twenty-second transistor T22 is turned on, a fourth signal transmitted by the fourth detection line 240 is transmitted to the fourth transmission line 94, which and the fourth transmission line 94 transmits the fourth signal to a second data line connected to a B sub-pixel and a R sub-pixel in the display area.

In an exemplary implementation, the twenty-third connection electrode 323 may be arranged on a side of the twenty-third gate electrode 223 in the second detection sub-unit in the direction opposite to the first direction X. The twenty-third connection electrode 323 is connected to the second region of the twenty-third active layer 123 through the forty-sixth via K46 on one hand, and the twenty-third connection electrode 323 is connected to the forty-second connection block 94-2 of the fourth transmission line 94 through the fifty-third via K53 on the other hand, so that the twenty-third transistor T23 controls on and off between the fourth detection line 240 and the fourth transmission line 94. When the twenty-third transistor T23 is turned on, a fourth signal transmitted by the fourth detection line 240 is transmitted to the fourth transmission line 94, and the fourth transmission line 94 transmits the fourth signal to a second data line connected to a B sub-pixel and a R sub-pixel in the display area.

In an exemplary implementation, the twenty-fourth connection electrode 324 may be arranged on a side of the twenty-fourth gate electrode 224 in the second detection sub-unit in the first direction X. The twenty-fourth connection electrode 324 is connected to the second region of the twenty-fourth active layer 124 through the forty-eighth via K48 on one hand, and the twenty-fourth connection electrode 324 is connected to the forty-third connection block 94-3 of the fourth transmission line 94 through the fifty-fourth via K54 on the other hand, so that the twenty-fourth transistor T24 controls on and off between the sixth detection line 260 and the fourth transmission line 94. When the twenty-fourth transistor T24 is turned on, a sixth signal transmitted by the sixth detection line 260 is transmitted to the fourth transmission line 94, and the fourth transmission line 94 transmits the sixth signal to a second data line connected to a B sub-pixel and a R sub-pixel in the display area.

In an exemplary implementation, the twenty-fifth connection electrode 325 may be arranged on a side of the twenty-fifth gate electrode 225 in the second detection sub-unit in the direction opposite to the first direction X. The twenty-fifth connection electrode 325 is connected to the second region of the twenty-fifth active layer 125 through the fiftieth via K50 on one hand, and the twenty-fifth connection electrode 325 is connected to the forty-fourth connection block 94-4 of the fourth transmission line 94 through the fifty-fifth via K55 on the other hand, so that the twenty-fifth transistor T25 controls on and off between the sixth detection line 260 and the fourth transmission line 94. When the twenty-fifth transistor T25 is turned on, a sixth signal transmitted by the sixth detection line 260 is transmitted to the fourth transmission line 94, and the fourth transmission line 94 transmits the sixth signal to a second data line connected to a B sub-pixel and a R sub-pixel in the display area.

In an exemplary implementation, the first insulation layer, the second insulation layer, the third insulation layer and the fourth insulation layer may be made of any one or more of silicon oxide (SiOx), silicon nitride (SiNx) and silicon oxynitride (SiON), and may be in a single layer, multiple layers or a composite layer. The first insulation layer may be referred to as a buffer layer and used for improving a water and oxygen resistance capability of the base substrate. The second insulation layer and the third insulation layer may be referred to as Gate Insulator (GIs) layers. The fourth insulation layer may be referred to as an Interlayer Dielectric (ILD) layer. The first conductive thin film, the second conductive thin film, and the third conductive thin film may be made of a metal material, for example, any one or more of Argentum (Ag), Copper (Cu), Aluminum (Al), Titanium (Ti), and Molybdenum (Mo), or an alloy material of the abovementioned metals, for example, an Aluminum-Neodymium alloy (AlNd) or a Molybdenum-Niobium alloy (MoNb), and may be in a single-layer structure, or a multilayer composite structure such as Ti/Al/Ti. The active layer thin film may be made of materials, such as amorphous indium gallium zinc oxide (a-IGZO), zinc oxynitride (ZnON), indium zinc tin oxide (IZTO), amorphous silicon (a-Si), polycrystalline silicon (p-Si), hexathiophene, and polythiophene. Namely, the present disclosure is applicable to transistors prepared based on oxide technology, silicon technology and organic substances technology.

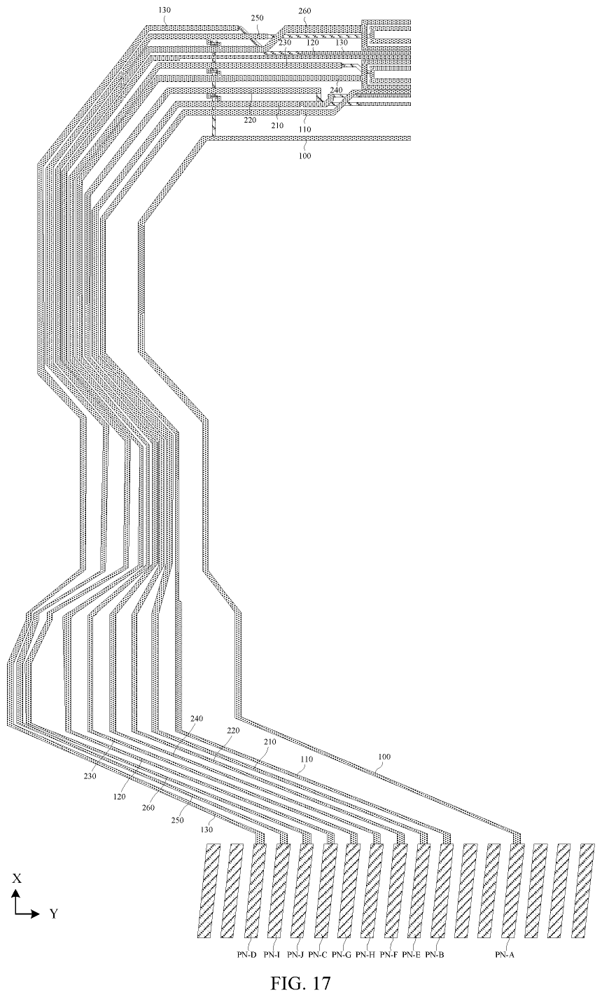

FIG. 17 is a schematic diagram of a structure of a detection circuit connected to a pin according to an exemplary embodiment of the present disclosure. As shown in FIG. 17, the bonding pin region in the bonding area may at least include a switching control pin PN-A, a first control pin PN-B, a second control pin PN-C, a third control pin PN-D, a first detection pin PN-E, a second detection pin PN-F, a third detection pin PN-G, a fourth detection pin PN-H, a fifth detection pin PN-I, and a sixth detection pin PN-J.

In an exemplary implementation, the switching control pin PN-A may be connected to a switching control line 100, the first control pin PN-B may be connected to a first control line 110, the second control pin PN-C may be connected to a second control line 120, the third control pin PN-D may be connected to a third control line 130, the first detection pin PN-E may be connected to a first detection line 210, the second detection pin PN-F may be connected to a second detection line 220, the third detection pin PN-G may be connected to a third detection line 230, the fourth detection pin PN-H may be connected to a fourth detection line 240, the fifth detection pin PN-I may be connected to a fifth detection line 250, and the sixth detection pin PN-J may be connected to a sixth detection line 260.

In an exemplary implementation, multiple signal lines of the detection circuit may extend from a bonding pin region to a detection circuit region in form of bent lines, which is not limited herein in the present disclosure.

The structure of the detection circuit shown in the present disclosure and the preparation process thereof are merely exemplary description. In an exemplary implementation, corresponding structures may be changed and patterning processes may be added or reduced according to actual needs, and the detection circuit may be provided with other electrodes, leads and film layers, which are not limited here in the present disclosure.

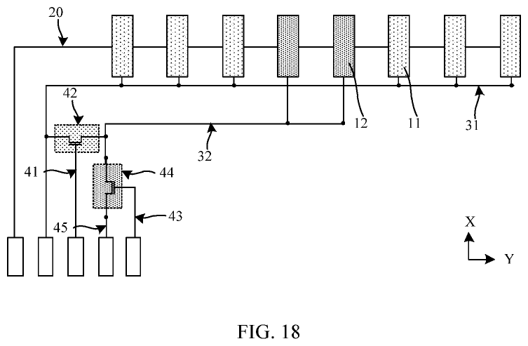

FIG. 18 is an equivalent circuit diagram of another detection circuit according to an exemplary embodiment of the present disclosure. As shown in FIG. 18, the detection circuit may include multiple first detection sub-units 11, multiple second detection sub-units 12, at least one control line 20, at least one first signal line 31, at least one second signal line 32, at least one switching control line 41, at least one switching unit 42, at least one switch control line 43, and at least one switch unit 44.

In an exemplary implementation, the multiple first detection sub-units 11 and the multiple second detection sub-units 12 may each include a control end, an input end and an output end, the multiple first detection sub-units 11 and the multiple second detection sub-units 12 may be sequentially arranged at set intervals along the second direction Y. Positions of the multiple first detection sub-units 11 may be in one-to-one correspondence to positions of multiple first data lines D1 in the display area, and positions of the multiple second detection sub-units 12 may be in one-to-one correspondence to positions of multiple second data lines D2 in the display area.

In an exemplary implementation, one end of the at least one control line 20 is connected correspondingly to a control pin of the bonding pin region, the other end at least one of the control line 20 is connected simultaneously to control ends of the multiple first detection sub-units 11 and the multiple second detection sub-units 12, and the control line 20 is configured to control multiple first detection sub-units 11 and multiple second detection sub-units 12 to be turned on or turned off.

In an exemplary implementation, one end of the at least one first signal line 31 is connected correspondingly to a first signal pin of the bonding pin region, the other end of the at least one first signal line 31 is connected to input ends of multiple first detection sub-units 11, and output ends of the multiple first detection sub-units 11 are connected correspondingly to the multiple first data lines D1 in the display area.

In an exemplary implementation, one end of the at least one second signal line 32 is connected to a switch second end of the switch unit 44, the other end of the at least one second signal line 32 is connected to the input ends of multiple second detection sub-units 12, and the output ends of the multiple second detection sub-units 12 are connected correspondingly to the multiple second data lines D2 in the display area.

In an exemplary implementation, one end of the at least one switching control line 41 is connected to a switching pin in the bonding pin region, the other end of the at least one switching control line 41 is connected to a switching control end of the switching unit 42, the first switching end of the switching unit 42 is connected to the at least one first signal line 31, the second switching end of the switching unit 42 is connected to the at least one second signal line 32, and the switching unit 42 is configured to isolate or turn on the at least one first signal line 31 and the at least one second signal line 32 under the control of the switching control line 41. When the at least one first signal line 31 and the at least one second signal line 32 are isolated from each other, the at least one first signal line 31 and the at least one second signal line 32 output different aging voltage signals, and when the at least one first signal line 31 and the at least one second signal line 32 are turned on, the at least one first signal line 31 and the at least one second signal line 32 output a same Light-on voltage signal.

In an exemplary implementation, one end of the at least one switch control line 43 is connected to a switch pin in the bonding pin region, the other end of the at least one switch control line 43 is connected to a switch control end of the switch unit 44, a switch first end of the switch unit 44 is connected to one end of the signal lead 45, a switch second end of the switch unit 44 is connected to at least one second signal line 32, the other end of the signal lead 45 is connected to a second signal pin in the bonding pin region, and the switch unit 44 is configured to isolate or turn on the signal lead 45 and the at least one second signal line 32 under the control of the switch control line 43. When the signal lead 45 and the at least one second signal line 32 are isolated from each other, the at least one first signal line 31 and the at least one second signal line 32 are turned on, and the at least one first signal line 31 and the at least one second signal line 32 output a same Light-on voltage signal. When the signal lead 45 and the at least one second signal line 32 are turned on, the at least one first signal line 31 and the at least one second signal line 32 are isolated, and the at least one first signal line 31 and the at least one second signal line 32 output different aging voltage signals.

In an exemplary implementation, the switch unit 44 may include a switch transistor, wherein a control electrode of the switch transistor is connected to a switch control line 43, a first electrode of the switch transistor is connected to a signal lead 45, and a second electrode of the switch transistor is connected to a second signal line 32.

In an exemplary implementation, an operating process of the aging procedure of the detection circuit of this exemplary embodiment is as follows: the external apparatus outputs a control signal through a control pin, outputs a turn-off signal through a switching pin, outputs a turn-on signal through a switch pin, outputs a first aging voltage signal through a first signal pin, and outputs a second aging voltage signal through a second signal pin. A control signal transmitted by a control line 20 controls multiple first detection sub-units 11 and multiple second detection sub-units 12 to be turned on. A turn-off signal transmitted by a switching control line 41 controls a switching unit 42 to be turned off, such that the first signal line 31 and the second signal line 32 are isolated, and a turn-on signal transmitted by a switching control line 43 controls a switch unit 44 to be turned on, such that a signal lead line 45 and the second signal line 32 are turned on. Multiple first detection sub-units 11 that are turned on output a first aging voltage signal transmitted by the first signal line 31 to multiple first data lines D1 in the display area respectively, and perform aging treatment on first sub-pixels in the first display area by using the first aging voltage signal. Multiple second detection sub-units 12 that are turned on output a second aging voltage signal transmitted by the second signal line 32 to multiple second data lines D2 in the display area respectively, and perform aging treatment on second sub-pixels in the second display area by using the second aging voltage signal, wherein the aging voltages in the first display area and the second display area are different.

In an exemplary implementation, an operating process of Light-on detection by the detection circuit of this exemplary embodiment is as follows: the external apparatus outputs a control signal through a control pin, outputs a turn-on signal through a switching pin, outputs a turn-off signal through a switch pin, outputs a Light-on voltage signal through a first signal pin or outputs a Light-on voltage signal through a second signal pin. A control signal transmitted by a control line 20 controls multiple first detection sub-units 11 and multiple second detection sub-units 12 to be turned on. A turn-off signal transmitted by a switch control line 43 controls a switch unit 44 to be turned off, such that a signal lead 45 and a second signal line 32 are isolated, and a turn-on signal transmitted by a switch control line 41 controls a switching unit 42 to be turned on, such that the first signal line 31 and the second signal line 32 are communicated, and the first signal line 31 and the second signal line 32 transmit a same Light-on voltage signal. Multiple first detection sub-units 11 and multiple second detection sub-units 12 that are turned on output the Light-on voltage signal to multiple first data lines D1 and multiple second data lines D2 in the display area respectively, and perform Light-on detection on sub-pixels in the first display area and the second display area using the same Light-on voltage signal.

In the technical scheme of aging by areas and overall Light-on provided by this exemplary embodiment, not only the aging voltages in the first display area and the second display area are different, the brightness difference between the first display area and the second display area can be eliminated. The same Light-on voltage are used for the first display area and the second display area, so that the uniformity of pictures can be ensured, and the reliability of aging by areas and overall Light-on can be improved by use of a switch unit.

An exemplary embodiment of the present disclosure further provides a display apparatus, which includes the display substrate of the foregoing embodiments. The display apparatus may be any product or component with a display function, such as a mobile phone, a tablet computer, a television, a display, a laptop computer, a digital photo frame, or a navigator.

Those of ordinary skills in the art should understand that modifications or equivalent replacements of the technical solutions of the present disclosure may be made without departing from the spirit and scope of the technical solutions of the present disclosure, and shall all fall within the scope of the claims of the present disclosure.

1. A display substrate, comprising a display area and a bonding area located on a side of the display area, wherein the display area comprises a first display area and a second display area, the first display area at least partially surrounds the second display area, the first display area is configured to display an image, and the second display area is configured to display an image and allow light to transmit; the first display area comprises a plurality of first sub-pixels and at least one first data line connected to the first sub-pixels, and the second display area comprises a plurality of second sub-pixels and at least one second data line connected to the second sub-pixels; the bonding area comprises a detection circuit, wherein the detection circuit comprises control lines, first signal lines, second signal lines, at least one first detection sub-unit and at least one second detection sub-unit; a control end of a first detection sub-unit is connected to a control line, an input end of the first detection sub-unit is connected to a first signal line, an output end of the first detection sub-unit is connected to a first data line, and the first detection sub-unit is configured to output a signal transmitted by the first signal line to the first data line; a control end of a second detection sub-unit is connected to a control line, an input end of the second detection sub-unit is connected to a second signal line, an output end of the second detection sub-unit is connected to a second data line, and the second detection sub-unit is configured to output a signal transmitted by the second signal line to the second data line.

2. The display substrate according to claim 1, wherein the control lines comprise a first control line, a second control line and a third control line, the first signal lines comprise a first detection line, a third detection line and a fifth detection line, the second signal lines comprise a second detection line, a fourth detection line, and a sixth detection line, the first detection sub-unit comprises an eleventh switch unit, a twelfth switch unit and a thirteenth switch unit, and the second detection sub-unit comprises a twenty-first switch unit, a twenty-second switch unit and a twenty-third switch unit; the eleventh switch unit is configured to transmit a signal transmitted by the first detection line to a first data line connected to a first color sub-pixel in the first display area under control of the first control line; the twelfth switch unit is configured to transmit a signal transmitted by the third detection line to a first data line connected to a second color sub-pixel in the first display area under control of the second control line; the thirteenth switch unit is configured to transmit a signal transmitted by the fifth detection line to a first data line connected to a third color sub-pixel in the first display area under control of the third control line; the twenty-first switch unit is configured to transmit a signal transmitted by the second detection line to a second data line connected to a first color sub-pixel in the second display area under the control of the first control line; the twenty-second switch unit is configured to transmit a signal transmitted by the fourth detection line to a second data line connected to a second color sub-pixel in the second display area under the control of the second control line; and the twenty-third switch unit is configured to transmit a signal transmitted by the sixth detection line to a second data line connected to a third color sub-pixel in the second display area under the control of the third control line.

3. The display substrate according to claim 2, wherein a control end of the eleventh switch unit is connected to the first control line, an input end of the eleventh switch unit is connected to the first detection line, and an output end of the eleventh switch unit is connected to the first data line connected to the first color sub-pixel in the first display area; and a control end of the twenty-first switch unit is connected to the first control line, an input end of the twenty-first switch unit is connected to the second detection line, and an output end of the twenty-first switch unit is connected to the second data line connected to the first color sub-pixel in the second display area.

4. The display substrate according to claim 3, wherein the eleventh switch unit comprises at least one eleventh transistor, and a control electrode of an eleventh transistor is connected to the first control line, a first electrode of the eleventh transistor is connected to the first detection line, and a second electrode of the eleventh transistor is connected to the first data line connected to the first color sub-pixel in the first display area; and the twenty-first switch unit comprises at least one twenty-first transistor, a control electrode of a twenty-first transistor is connected to the first control line, a first electrode of the twenty-first transistor is connected to the second detection line, and a second electrode of the twenty-first transistor is connected to the second data line connected to the first color sub-pixel in the second display area.

5. The display substrate according to claim 2, wherein a control end of the twelfth switch unit is connected to the second control line, an input end of the twelfth switch unit is connected to the third detection line, and an output end of the twelfth switch unit is connected to the first data line connected to the second color sub-pixel in the first display area; and a control end of the twenty-second switch unit is connected to the second control line, an input end of the twenty-second switch unit is connected to the fourth detection line, and an output end of the twenty-second switch unit is connected to the second data line connected to the second color sub-pixel in the second display area.

6. The display substrate according to claim 5, wherein the twelfth switch unit comprises at least one twelfth transistor and at least one thirteenth transistor, and control electrodes of the at least one twelfth transistor and the at least one thirteenth transistor are connected to the second control line, first electrodes of the at least one twelfth transistor and the at least one thirteenth transistor are connected to the third detection line, and second electrodes of the at least one twelfth transistor and the at least one thirteenth transistor are connected to the first data line connected to the second color sub-pixel in the first display area; and the twenty-second switch unit comprises at least one twenty-second transistor and at least one twenty-third transistor, control electrodes of the at least one twenty-second transistor and the at least one twenty-third transistor are connected to the second control line, first electrodes of the at least one twenty-second transistor and the at least one twenty-third transistor are connected to the fourth detection line, and second electrodes of the at least one twenty-second transistor and the at least one twenty-third transistor are connected to the second data line connected to the second color sub-pixel in the second display area.

7. The display substrate according to claim 2, wherein a control end of the thirteenth switch unit is connected to the third control line, an input end of the thirteenth switch unit is connected to the fifth detection line, and an output end of the thirteenth switch unit is connected to the first data line connected to the third color sub-pixel in the first display area; a control end of the twenty-third switch unit is connected to the third control line, an input end of the twenty-third switch unit is connected to the sixth detection line, and an output end of the twenty-third switch unit is connected to the second data line connected to the third color sub-pixel in the second display area.

8. The display substrate according to claim 7, wherein the thirteenth switch unit comprises at least one fourteenth transistor and at least one fifteenth transistor, and control electrodes of the at least one fourteenth transistor and the at least one fifteenth transistor are connected to the third control line, first electrodes of the at least one fourteenth transistor and the at least one fifteenth transistor are connected to the fifth detection line, and second electrodes of the at least one fourteenth transistor and the at least one fifteenth transistor are connected to the first data line connected to the third color sub-pixel in the first display area; and the twenty-third switch unit comprises at least one twenty-fourth transistor and at least one twenty-fifth transistor, control electrodes of the at least one twenty-fourth transistor and the at least one twenty-fifth transistor are connected to the third control line, first electrodes of the at least one twenty-fourth transistor and the at least one twenty-fifth transistor are connected to the sixth detection line, and second electrodes of the at least one twenty-fourth transistor and the at least one twenty-fifth transistor are connected to the second data line connected to the third color sub-pixel in the second display area.

9. The display substrate according to claim 1, wherein the detection circuit further comprises a switching control line and a switching unit, and a control electrode of the switching unit is connected to the switching control line, a first electrode of the switching unit is connected to the first signal lines, a second electrode of the switching unit is connected to the second signal lines, and the switching unit is configured to isolate or turn on the first signal lines and the second signal lines under control of the switching control line.

10. The display substrate according to claim 9, wherein the switching unit comprises a first switching sub-unit, a second switching sub-unit and a third switching sub-unit; the first signal lines comprise a first detection line, a third detection line and a fifth detection line; the second signal lines comprise a second detection line, a fourth detection line and a sixth detection line; a control electrode of the first switching sub-unit is connected to the switching control line, a first electrode of the first switching sub-unit is connected to the first detection line, and a second electrode of the first switching sub-unit is connected to the second detection line; a control electrode of the second switching sub-unit is connected to the switching control line, a first electrode of the second switching sub-unit is connected to the third detection line, and a second electrode of the second switching sub-unit is connected to the fourth detection line; and a control electrode of the third switching sub-unit is connected to the switching control line, a first electrode of the third switching sub-unit is connected to the fifth detection line, and a second electrode of the third switching sub-unit is connected to the sixth detection line.

11. The display substrate according to claim 10, wherein the first switching sub-unit comprises two first transistors connected in series, control electrodes of the two first transistors are connected to the switching control line, a first electrode of one first transistor is connected to the first detection line, a second electrode of the other first transistor is connected to the second detection line, and a second electrode of the one first transistor and a first electrode of the other first transistor are connected to each other; or
the second switching sub-unit comprises two second transistors connected in series, and control electrodes of the two second transistors are connected to the switching control line, a first electrode of one second transistor is connected to the third detection line, a second electrode of the other second transistor is connected to the fourth detection line, and a second electrode of the one second transistor and a first electrode of the other second transistor are connected to each other; or
the third switching sub-unit comprises two third transistors connected in series, and control electrodes of the two third transistors are connected to the switching control line, a first electrode of one third transistor is connected to the fifth detection line, a second electrode of the other third transistor is connected to the sixth detection line, and a second electrode of the one third transistor and a first electrode of the other third transistor are connected to each other.

12-13. (canceled)

14. The display substrate according to claim 9, wherein the detection circuit further comprises a switch control line, a switch unit and a signal lead, and a control electrode of the switch unit is connected to the switch control line, a first electrode of the switch unit is connected to the signal lead, a second electrode of the switch unit is connected to the second signal line, and the switch unit is configured to isolate or turn on the signal lead and the second signal line under control of the switch control line; when the signal lead and the second signal line are turned on, the first signal line and the second signal line are isolated from each other, and the first signal line and the second signal line output different aging voltage signals; and when the signal lead and the second signal line are isolated from each other, the first signal line and the second signal line are turned on, and the first signal line and the second signal line output a same Light-on voltage signal.

15. The display substrate according to claim 1, wherein on a plane perpendicular to the display substrate, the display substrate comprises a semiconductor layer, a first conductive layer, a second conductive layer and a third conductive layer arranged sequentially on a base substrate, and the semiconductor layer comprises active layers of a plurality of transistors in the switching unit, active layers of a plurality of transistors in the at least one first detection sub-unit and active layers of a plurality of transistors in the at least one second detection sub-unit, the first conductive layer comprises gate electrodes of the plurality of transistors in the switching unit, gate electrodes of the plurality of transistors in the at least one first detection sub-unit, and gate electrodes of the plurality of transistors in the at least one second detection sub-unit, and the third conductive layer comprises the control lines, the first signal lines, and the second signal lines.

16. The display substrate according to claim 15, wherein the control lines comprise a first control line, a second control line and a third control line, and at least one of the first control line, the second control line and the third control line comprises a control lead-out line and a control extension line, the control lead-out line and the control extension line are connected through a signal connection line arranged in the first conductive layer, and the control lead-out line and the control extension line are arranged in the third conductive layer; or
the first signal lines comprise a first detection line, a third detection line and a fifth detection line, the second signal lines comprise a second detection line, a fourth detection line and a sixth detection line, and at least one of the first detection line, the second detection line, the third detection line, the fourth detection line, the fifth detection line and the sixth detection line comprises a detection lead-out line and a detection extension line, and the detection lead-out line and the detection extension line are connected through a signal connection line arranged in the first conductive layer, and the detection lead-out line and the detection extension line are arranged in the third conductive layer; or
the first conductive layer further comprises a switching connection line, the third conductive layer further comprises a switching control line, and the switching connection line is connected to the switching control line through a via, and the switching connection line and gate electrodes of a plurality of transistors in the switching unit are connected to each other to form an integral structure; or
a first detection sub-unit comprises a first transmission line and a second transmission line, and the first transmission line is connected to a first data line connected to a first color sub-pixel in the first display area, and the second transmission line is connected to a first data line connected to a second color sub-pixel and a third color sub-pixel in the first display area; and
the first transmission line is arranged in the first conductive layer, and the second transmission line is arranged in the second conductive layer.

17-19. (canceled)

20. The display substrate according to claim 16, wherein a twenty-first connection block and a twenty-second connection block are provided on the second transmission line; the twenty-first connection block is connected to a twelfth active layer and a thirteenth active layer in the first detection sub-unit through a twelfth connection electrode, and the twenty-first connection block is arranged between the twelfth active layer and the thirteenth active layer; and the twenty-second connection block is connected to a fourteenth active layer and a fifteenth active layer in the first detection sub-unit through a thirteenth connection electrode, and the twenty-second connection block is arranged between the fourteenth active layer and the fifteenth active layer.

21. The display substrate according to claim 20, wherein the twelfth connection electrode and the thirteenth connection electrode are arranged in the third conductive layer.

22. The display substrate according to claim 15, wherein a second detection sub-unit comprises a third transmission line and a fourth transmission line, and the third transmission line is connected to a second data line connected to a first color sub-pixel in the second display area, and the fourth transmission line is connected to a second data line connected to a second color sub-pixel and a third color sub-pixel in the second display area, and the third transmission line is arranged in the first conductive layer, and the fourth transmission line is arranged in the second conductive layer.

23. The display substrate according to claim 22, wherein a forty-first connection block, a forty-second connection block, a forty-third connection block and a forty-fourth connection block are provided on the fourth transmission line; the forty-first connection block is connected to a twenty-second active layer in the second detection sub-unit through a twenty-second connection electrode, and the forty-first connection block is arranged on a side of the twenty-second active layer in a first direction; the forty-second connection block is connected to a twenty-third active layer in the second detection sub-unit through a twenty-third connection electrode, and the forty-second connection block is arranged on a side of the twenty-third active layer in a direction opposite to the first direction; the forty-third connection block is connected to a twenty-fourth active layer in the second detection sub-unit through a twenty-fourth connection electrode, and the forty-third connection block is arranged on a side of the twenty-fourth active layer in the first direction; the forty-fourth connection block is connected to a twenty-fifth active layer in the second detection sub-unit through a twenty-fifth connection electrode, and the forty-fourth connection block is arranged on a side of the twenty-fifth active layer in opposite direction to the first direction; and the first direction is an extension direction of the fourth transmission line.

24. The display substrate according to claim 23, wherein the twenty-second connection electrode, the twenty-third connection electrode, the twenty-fourth connection electrode, and the twenty-fifth connection electrode are arranged in the third conductive layer.

25. A display apparatus, comprising the display substrate according to claim 1.
